(19) United States
(12) Patent Application Publication
(10) Pub. No.: US 2024/0317916 A1
(43) Pub. Date: Sep. 26, 2024

(54) CURABLE RESIN COMPOSITION AND CURED PRODUCT

(71) Applicant: DIC CORPORATION, Tokyo (JP)

(72) Inventors: Ryuichi Matsuoka, Sakura-chi (JP); Hiroyoshi Kannari, Sakura-shi (JP); Lichen Yang, Sakura-shi (JP)

(73) Assignee: DIC Corporation, Tokyo (JP)

(21) Appl. No.: 18/577,915

(22) PCT Filed: Jun. 30, 2022
(86) PCT No.: PCT/JP2022/026139

§ 371 Date: Jan. 9, 2024

(30) Foreign Application Priority Data
Jul. 29, 2021 (JP) 2021-124129

(51) Int. Cl. C08F 222/10; C08J 5/24; C09D 4/00; C09D 135/02; H05K 1/03

(52) U.S. Cl. CPC C08F 222/104; C08J 5/24; C09D 4/00; C09D 135/02; H05K 1/0366; C08J 2335/02

(57) ABSTRACT

An object is to provide a curable resin composition that can provide its cured product with excellent heat resistance (a high glass transition temperature) and dielectric properties (low dielectric properties) and the cured product. Specifically, provided is a curable resin composition containing a curable resin (A) having a structure represented by General Formula (1) below and a curable resin (B1) having a structure represented by General Formula (2-1) below and/or a curable compound (B2) represented by General Formula (2-2) below:

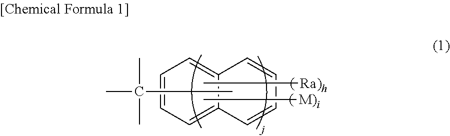

in General Formula (1) above, the details of the substituents and the number of the substituents are as described in the present specification.

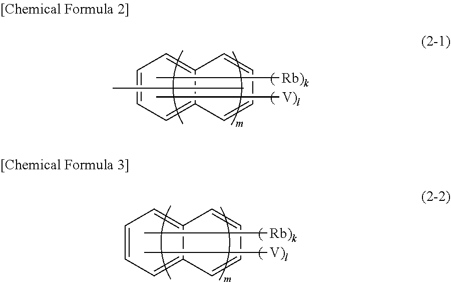

in General Formulae (2-1) and (2-2) above, the details of the substituents and the number of the substituents are as described in the present specification.

### TECHNICAL FIELD

The present invention relates to a curable resin composition containing a curable resin having a specific structure and a cured product obtained by the curable resin composition.

### BACKGROUND ART

Along with an increase in the volume of information communication in recent years, information communication in high frequency bands has become to be performed vigorously, and electric materials having more excellent electrical properties, in particular, a low dielectric constant and a low dielectric loss tangent have been demanded in order to reduce transmission loss in high frequency bands.

Furthermore, printed boards or electronic components in which these electric insulating materials are used are exposed to high-temperature solder reflow during mounting, and thus materials having excellent heat resistance and indicating a high glass transition temperature are required. Recently in particular, lead-free solders, which have high melting points, have been used from the viewpoint of environmental issues, and thus requirements for electric insulating materials with higher heat resistance have been increasing.

In response to these requirements, curable resins containing vinyl groups having various chemical structures have been conventionally developed. As such curable resins, curable resins such as divinylbenzyl ether of bisphenol and poly(vinylbenzyl) ether of novolac have been proposed, for example (refer to PTL 1 and PTL 2, for example). However, these vinylbenzyl ethers cannot give cured products with sufficiently low dielectric properties, and the obtained cured products are problematic for stable use in high frequency bands. Furthermore, divinylbenzyl ether of bisphenol does not have sufficiently high heat resistance.

For the vinylbenzyl ethers with the above-described properties improved, several poly(vinylbenzyl) ethers with specific structures have been developed in order to improve induction properties and the like (refer to PTL 3 to PTL 5, for example). However, although attempts to reduce the dielectric loss tangent and attempts to improve heat resistance have been made, improvement in these properties is still not sufficient, and further improvement in properties is desired.

Thus, conventional curable resins containing vinyl groups including poly(vinylbenzyl) ether do not provide cured products having both a low dielectric loss tangent required for electric insulating materials, especially for electric insulating materials ready for high frequency, and heat resistance capable of withstanding lead-free soldering.

### CITATION LIST

### Patent Literature

PTL 1: Japanese Unexamined Patent Application Publication No. S63-68537
PTL 2: Japanese Unexamined Patent Application Publication No. S64-65110
PTL 3: Japanese Translation of PCT Application Publication No. H01-503238
PTL 4: Japanese Unexamined Patent Application Publication No. H09-31006
PTL 5: Japanese Unexamined Patent Application Publication No. 2005-314556

### SUMMARY OF INVENTION

### Technical Problem

Thus, an object of the present invention is to provide a curable resin composition that can provide its cured product with excellent heat resistance (a high glass transition temperature) and dielectric properties (low dielectric properties) and the cured product.

### Solution to Problem

Thus, in order to achieve the object, the inventors of the present invention have earnestly studied to find out that a cured product obtained from a curable resin composition containing a methacryloyloxy group-containing compound and an aromatic vinyl group-containing compound has excellent heat resistance and low dielectric properties to complete the present invention.

Specifically, the present invention relates to a curable resin composition containing a curable resin (A) having a structure represented by General Formula (1) below and a curable resin (B1) having a structure represented by General Formula (2-1) below and/or a curable compound (B2) represented by General Formula (2-2) below:

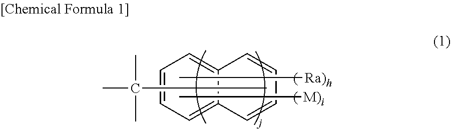

in General Formula (1) above, Ras are each independently an alkyl group, an aryl group, an aralkyl group, or a cycloalkyl group with a carbon number of 1 to 12; M is a methacryloyloxy group; h and i each independently indicate an integer of 1 to 4; and j indicates an integer of 0 to 2.

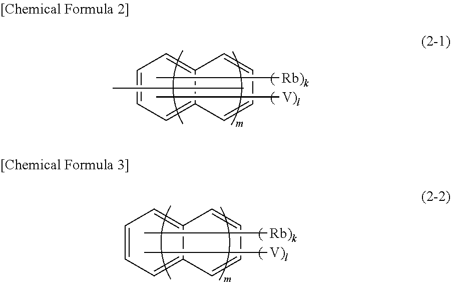

in General Formulae (2-1) and (2-2) above, Rbs are each independently an alkyl group, an aryl group, an aralkyl group, or a cycloalkyl group with a carbon number of 1 to 12; V is a vinyl group; k indicates an integer of 0 to 4; 1 indicates an integer of 1 to 4; and m indicates an integer of 0 to 2.

The present invention relates to a cured product obtained by subjecting the curable resin composition to a curing reaction.

### Advantageous Effects of Invention

The present invention is a curable resin composition containing the curable resin (A) and the curable resin (B1) and/or the curable compound (B2). A cured product obtained from the curable resin composition can contribute to heat resistance (a high glass transition temperature) and dielectric properties (low dielectric properties), which is useful.

### DESCRIPTION OF EMBODIMENTS

The following describes the present invention in detail.

### <Curable Resin (A)>

The curable resin composition of the present invention contains a curable resin (A) having a structure represented by General Formula (1) below:

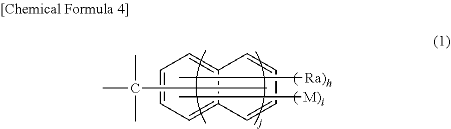

in General Formula (1) above, Ras are each independently an alkyl group, an aryl group, an aralkyl group, or a cycloalkyl group with a carbon number of 1 to 12; M is a methacryloyloxy group; h and i each independently indicate an integer of 1 to 4; and j indicates an integer of 0 to 2. In General Formula (1) above, Ra and M are only required to be bonded to any position on the aromatic ring, indicating that the bonding site with the carbon atom is any position on the aromatic ring.

In General Formula (1) above, Ras each independently represent an alkyl group, an aryl group, an aralkyl group, or a cycloalkyl group with a carbon number of 1 to 12 and is preferably an alkyl group, an aryl group, or a cycloalkyl group with a carbon number of 1 to 4. Being the alkyl group with a carbon number of 1 to 12 or the like reduces the planarity in the vicinity of any of a benzene ring, a naphthalene ring, and an anthracene ring described below, reduced crystallinity improves solvent solubility and lowers the melting point, and provides a preferred mode. Having the Ra creates steric hindrance and lowers molecular mobility, resulting in a cured product with a low dielectric loss tangent. Furthermore, the Ra is preferably positioned at the ortho position with respect to the cross-linking group M. At least the one Ra is preferably positioned at the ortho position of the cross-linking group M the molecular mobility of the cross-linking group M is further reduced due to the steric hindrance of the Ra, and a cured product with a much lower dielectric loss tangent can be obtained.

In General Formula (1) above, M is a methacryloyloxy group serving as the cross-linking group. Having the methacryloyloxy group in the curable resin composition provides a cured product having a lower dielectric loss tangent than that of other cross-linking groups (for example, a vinylbenzyl ether group, a dihydroxybenzene group, and the like).

The detailed reason why having the methacryloyloxy group provides a cured product developing low dielectric properties is not clear, but in the case of a vinylbenzyl ether group or the like contained in conventionally used curable resins, it has an ether group as a polar group, and in the case of having a dihydroxybenzene group, it has a plurality of hydroxy groups as polar groups, and it is presumed that the ester group based on the methacryloyloxy group as in the curable resin of the present invention having lower molecular mobility contributes to low dielectric properties (having a polar group having high polarity such as an ether group or a hydroxy group tends to make a dielectric constant and a dielectric tangent loss higher).

When the cross-linking group is the methacryloyloxy group, it contains a methyl group in the structure, and thus steric hindrance increases, and it is presumed that molecular mobility further reduces, resulting in a cured product with a much lower dielectric loss tangent. When there are a plurality of cross-linking groups, the cross-linking density increases, and heat resistance improves.

In General Formula (1) above, h indicates an integer of 1 to 4, is preferably an integer of 1 or 2, and is more preferably 2. Being within the above range achieves excellent reactivity and provides a preferred mode.

In General Formula (1) above, i indicates an integer of 1 to 4 and is preferably an integer of 1 or 2. Being within the above range ensures bendability, and provides a preferred mode.

In General Formula (1) above, j indicates an integer of 0 to 2, that is, when j is 0, it is a benzene ring; when j is 1, it is a naphthalene ring; when j is 2, it is an anthracene ring; and the benzene ring, with j being 0, is preferred. Being within the above range achieves excellent solvent solubility and provides a preferred mode.

In General Formula (1) above, at least one Ra on the aromatic ring and M are preferably positioned at the ortho position. At least one Ra is positioned at the ortho position of M, thereby constraining the molecular mobility of the methacryloyloxy group due to the steric hindrance of Ra, resulting in a lower dielectric loss tangent than that of the curable resin having the structure shown by General Formula (1) above, which provides a preferred mode.

Furthermore, General Formula (1) above is preferably represented by General Formula (1-1) below. That is, the structural formula described in General Formula (1-1) below has, in General Formula (1), 2 for h and 1 for j, has Ra positioned at the ortho positions on both sides of the methacryloyloxy group, and further fixes (limits) the aromatic ring to the benzene ring. The curable resin having such a structure shown by General Formula (1-1) below more constraints the molecular mobility of the methacryloyl group than in the case in which Ra is positioned only on one side and further reduces the dielectric loss tangent, and provides a preferred mode.

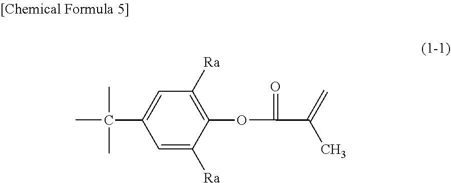

In General Formula (1-1) above, Ra is common to Ra in General Formula (1) above.

The curable resin (A), when it is a resin shown by any of General Formulae (A1) to (A3) below, is more preferred due to ease of obtaining industrial raw materials.

### <Curable Resin (A1)>

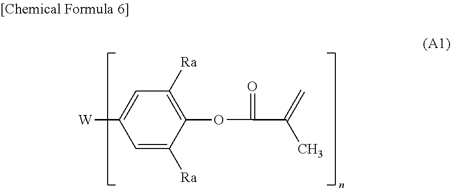

In General Formula (A1) above, Ras are each independently an alkyl group, an aryl group, an aralkyl group, or a cycloalkyl group with a carbon number of 1 to 12; W is a hydrocarbon with a carbon number of 2 to 15; and n indicates an integer of 3 to 5.

In General Formula (A1) above, W is a hydrocarbon with a carbon number of 2 to 15 and preferably a hydrocarbon with a carbon number of 2 to 10. By the carbon number being within the above range, the curable resin (A1) is a low molecular weight body and has a higher cross-linking density, a higher glass transition temperature of the resulting cured product, and more excellent heat resistance than in the case of a high molecular weight body, and provides a preferred mode. The carbon number is preferably 2 or more because the resulting curable resin is a high molecular weight body and has a lower cross-linking density of the resulting cured product, forms a film or the like more easily, and tends to have more excellent handleability, bendability, flexibility, and brittleness resistance than in the case in which the carbon number is less than 2. The carbon number is preferably 15 or less because the resulting curable resin is a low molecular weight body and has a higher ratio of the cross-linking group (the methacryloyl group) in the curable resin (A1) than in the case in which the carbon number is greater than 15 and, along with this, has an improved cross-linking density and has excellent heat resistance of the resulting cured product.

The hydrocarbon is not limited to a particular hydrocarbon so long as it is a hydrocarbon with a carbon number of 2 to 15 and is preferably any of aliphatic hydrocarbons such as alkanes, alkenes, and alkynes, for example. Examples thereof include aromatic hydrocarbons including an aryl group and compounds in which an aliphatic hydrocarbon and an aromatic hydrocarbon are combined with each other.

Among the aliphatic hydrocarbons, examples of the alkanes include ethane, propane, butane, pentane, hexane, and cyclohexane. Examples of the alkenes include ones including a vinyl group, a 1-methylvinyl group, a propenyl group, a butenyl group, a pentenyl group, or the like.

Examples of the alkynes include ones including an ethynyl group, a propynyl group, a butynyl group, a pentynyl group, a hexynyl group, or the like.

Examples of the aromatic hydrocarbons include ones including a phenyl group, a tolyl group, a xylyl group, a naphthyl group, or the like as the aryl group.

Examples of the compounds in which an aliphatic hydrocarbon and an aromatic hydrocarbon are combined with each other include ones including a benzyl group, a phenylethyl group, a phenylpropyl group, a tolylmethyl group, a tolylethyl group, a tolylpropyl group, a xylylmethyl group, a xylylethyl group, a xylylpropyl group, a naphthylmethyl group, a naphthylethyl group, a naphthylpropyl group, or the like.

Among the hydrocarbons, aliphatic hydrocarbons, aromatic hydrocarbons, and alicyclic hydrocarbons, each consisting only of carbon atoms and hydrogen atoms, are preferable from the viewpoint of obtaining cured products having low polarity and low dielectric properties (a low dielectric constant and a low dielectric loss tangent). Among them, hydrocarbons such as formulae (3-1) to (3-6) below, which have very low polarity and can be industrially employed, are preferred, and aliphatic hydrocarbons such as General Formulae (3-1) and (3-4) below are more preferred. In General Formula (3-1) below, k represents an integer of 0 to 5, is preferably 0 to 3. Rc in General Formulae (3-1), (3-2), and (3-4) to (3-6) below is preferably represented by a hydrogen atom or a methyl group.

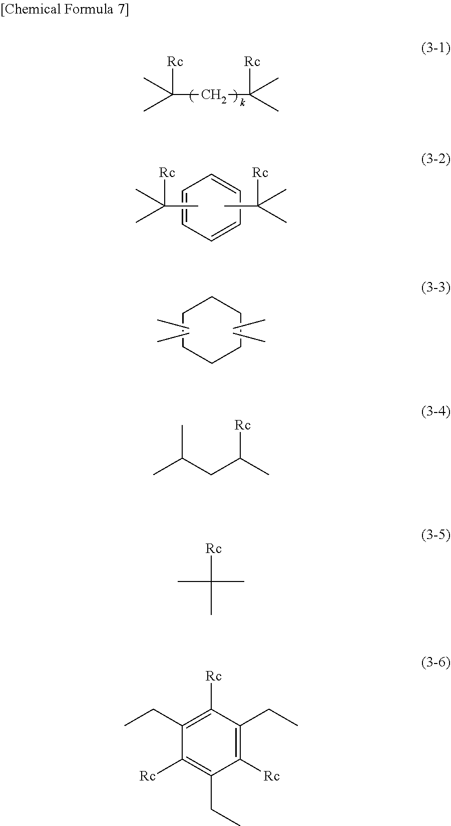

In General Formula (A1) above, n is the number of substituents, indicates an integer of 3 to 5, is preferably 3 or 4, and is more preferably 4. By n being within the above range, the curable resin (A1) is a low molecular weight body and has a higher cross-linking density, a higher glass transition temperature of the resulting cured product, and more excellent heat resistance than in the case of a high molecular weight body, and provides a preferred mode. Note that n is preferably 3 or more because the number of methacryloyloxy groups, which are cross-linking groups, increases, and the resulting cured product has a high cross-linking density and sufficient heat resistance. On the other hand, n is preferably 5 or less because the cross-linking density of the cured product is not excessively high, thus making it easy to form a film or the like and providing excellent handleability, bendability, flexibility, and brittleness resistance.

In General Formula (A1) above, Ra is common to Ra in General Formula (1) above.

### <Curable Resin (A2)>

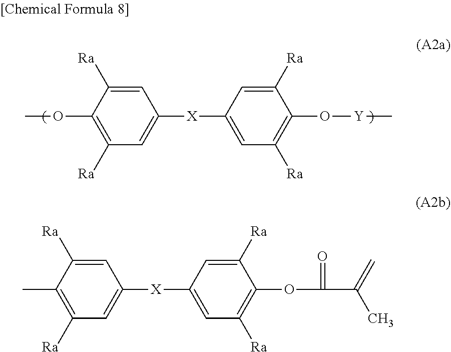

The curable resin (A2) has the above repeating unit (A2a) and the terminal structure (A2b), and in General Formula (A2a) or General Formula (A2b) above, Ras are each independently an alkyl group, an aryl group, an aralkyl group, or a cycloalkyl group with a carbon number of 1 to 12, X represents a hydrocarbon group, and Y indicates any of General Formulae (Y1) to (Y3) below:

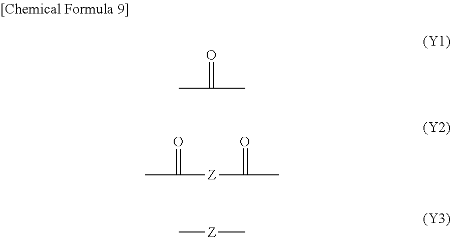

In General Formulae (Y1) to (Y3) above, Z indicates an alicyclic group, an aromatic group, or a heterocyclic group.

By the curable resin (A2) having the repeating unit represented by General Formula (A2a) above and the terminal structure represented by General Formula (A2b) above, the ester bond or the carbonate bond contained in the curable resin (A2) has lower molecular mobility than that of an ether group or the like, thus providing low dielectric properties (a low dielectric loss tangent in particular). In addition, the curable resin (A2) component having the methacryloyloxy group provides the resulting cured product with excellent heat resistance, and furthermore, having the ester bond or the carbonate bond with lower molecular mobility can obtain a cured product having not only low dielectric properties but also a high glass transition temperature.

In General Formulae (A2a) and (A2b) above, X may be any hydrocarbon group, but it is preferred to be represented by the structures of General Formulae (4) to (6) below from the viewpoint of ease of obtaining industrial raw materials, and especially the structure of General Formula (4) below is more preferred because of its good balance of heat resistance and low dielectric properties:

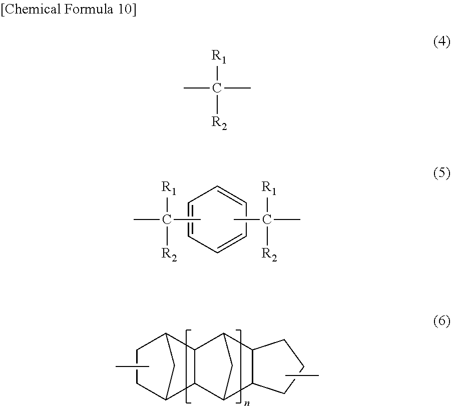

In General Formulae (4) to (6) above, R₁ and R₂ are each independently represented by a hydrogen atom, an alkyl group, an aryl group, an aralkyl group, or a cycloalkyl group with a carbon number of 1 to 12 or R₁ and R₂ may be bonded together to form a cyclic skeleton. The letter n indicates an integer of 0 to 2 and is preferably an integer of 0 or 1. By n being within the above range, high heat resistance is achieved, which is a preferred mode.

In General Formula (A2a) above, Y is represented by General Formula (Y1), (Y2), or (Y3) above and, from the viewpoint of heat resistance, is preferably General Formula (Y1) above.

In General Formulae (Y2) and (Y3) above, Z is represented by an alicyclic group, an aromatic group, or a heterocyclic group in order to obtain a cured product with high heat resistance and is preferably a structure represented by General Formulae (7) to (11) below. From the viewpoint of cost and heat resistance, especially the structure of General Formula (7) below (a benzene ring) is more preferable:

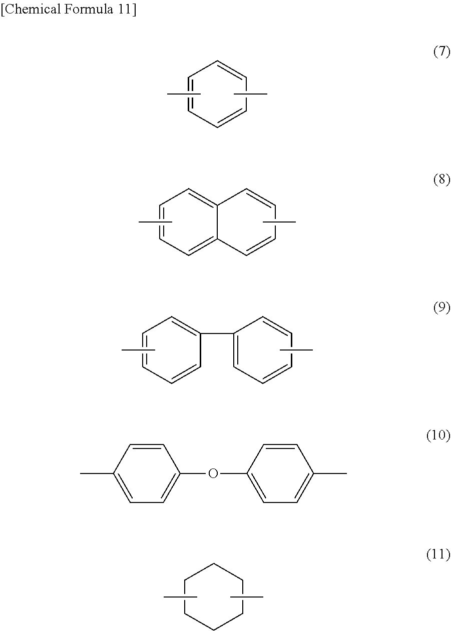

In General Formulae (A2a) and (A2b) above, Ra is common to Ra in General Formula (1) above.

The curable resin (A2) is characterized in that it has a repeating unit represented by General Formula (A2a) above and a terminal structure represented by General Formula (A2b) above and may contain other repeating units (structures) to the extent that the properties of the curable resin (A2) are not impaired.

The curable resin (A2) has a weight average molecular weight (Mw) of preferably 500 to 50,000, more preferably 1,000 to 10,000, and even more preferably 1,500 to 5,000. Being within the above range is preferable because it improves solvent solubility and makes processing workability favorable.

### <Curable Resin (A3)>

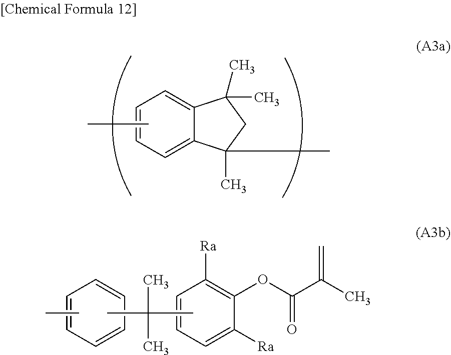

The curable resin (A3) has the above repeating unit (A3a) and the terminal structure (A3b), and in General Formula (A3b) above, Ras each independently indicate an alkyl group, an aryl group, an aralkyl group, or a cycloalkyl group with a carbon number of 1 to 12.

By General Formula (A3a) above having an indane skeleton, an alicyclic structure having an excellent balance of heat resistance and dielectric properties is introduced into the structure of the curable resin (A3), and the cured product produced using the curable resin (A3) has an excellent balance of heat resistance and dielectric properties (a low dielectric loss tangent in particular). In addition, by having the methacryloyl group as the terminal structure (A3b), steric hindrance increases, and much lower dielectric properties can be exhibited.

The curable resin (A3) has a weight average molecular weight (Mw) of preferably 500 to 50,000, more preferably 1,000 to 10,000, and even more preferably 1,500 to 5,000. Being within the above range improves solvent solubility is preferred because it makes processing workability favorable, and further provides the resulting cured product with excellent bendability and flexibility.

The curable resin (A) of the present invention is preferably one or more selected from the group consisting of the curable resins (A1) to (A3).

### <Curable Resin (B1) and Curable Compound (B2)>

The curable resin composition of the present invention contains a curable resin (B1) having a structure represented by General Formula (2-1) below and/or a curable compound (B2) having a structure represented by General Formula (2-2) below. In General Formulae (2-1) and (2-2) below, Rb and V are only required to be bonded to any position on the aromatic ring, indicating that in General Formula (2-1) below the bonding site with the carbon atom is any position on the aromatic ring.

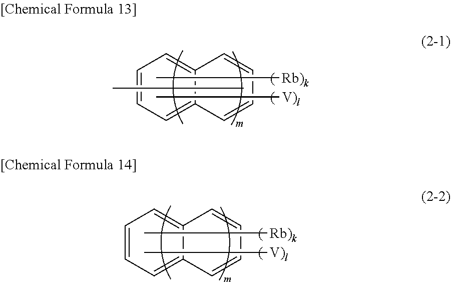

in General Formulae (2-1) and (2-2) above, Rbs are each independently an alkyl group, an aryl group, an aralkyl group, or a cycloalkyl group with a carbon number of 1 to 12; V is a vinyl group, k indicates an integer of 0 to 4; 1 indicates an integer of 1 to 4; and m indicates an integer of 0 to 2.
in General Formulae (2-1) and (2-2) above, Rbs are each independently an alkyl group, an aryl group, an aralkyl group, or a cycloalkyl group with a carbon number of 1 to 12.

In General Formulae (2-1) and (2-2) above, V indicates a vinyl group, and an aromatic vinyl group-containing compound (in the present specification, the aromatic vinyl group indicates a vinyl group directly bonded to an aromatic ring.) has high self-reactivity and sufficiently proceeds with a curing reaction. Furthermore, the aromatic vinyl group-containing compound has low polarity and thus has a low dielectric constant and a reduced dielectric loss tangent, and provides a preferred mode.

In General Formulae (2-1) and (2-2) above, k indicates an integer of 0 to 4 and is preferably an integer of 0 to 2. Being within the above range improves copolymerizability with a methacryloyloxy group and provides a preferred mode.

In General Formulae (2-1) and (2-2) above, 1 indicates an integer of 1 to 4 and is preferably an integer of 1 or 2. Being within the above range improves heat resistance and provides a preferred mode.

In General Formulae (2-1) and (2-2) above, m indicates an integer of 0 to 2, that is, when m is 0, it is a benzene ring; when m is 1, it is a naphthalene ring; when m is 2, it is an anthracene ring; and the benzene ring, with m being 0, is preferred. Being within the above range achieves excellent solvent solubility and provides a preferred mode.

As the curable resin (B1), any resin can be used without particular limitations so long as it has the structure represented by General Formula (2-1) above, but from the viewpoint of ease of obtaining industrial raw materials, preferred is a curable resin obtained using at least one type selected from, for example, styrene, methylstyrene, ethylstyrene, isopropylstyrene, 4-tert-butylstyrene, divinylbenzene, vinylnaphthalene, vinylanthracene, vinylbiphenyl, or the like, as a raw material.

As the curable compound (B2), any compound can be used without particular limitations so long as it is a compound represented by General Formula (2-2) above, but from the viewpoint of industrial availability, preferred is, for example, styrene, methylstyrene, ethylstyrene, isopropylstyrene, 4-tert-butylstyrene, divinylbenzene, vinylnaphthalene, vinylanthracene, vinylbiphenyl, bis(vinylphenyl)methane, 1,2-bis(vinylphenyl)ethane, 1,2-bis(vinylphenyl)butane, 1,6-bis(4-vinylphenyl)hexane, or the like.

The curable resin composition of the present invention is only required to contain at least one of the curable resin (B1) having the structure represented by General Formula (2-1) above and the curable compound (B2) having the structure represented by General Formula (2-2) above and may contain both the curable resins (B1) and (B2).

The curable resin composition of the present invention preferably has a mass ratio between the mass of the curable resin (A) and the total mass of the curable resin (B1) and/or the curable compound (B2) of 99:1 to 10:90. The mass ratio being 99:1 or less is preferred because it allows the curing reaction of the cured product to sufficiently proceed, and the resulting cured product has excellent heat resistance. The mass ratio being 10:90 or more is preferred because it allows the resulting cured product to increase in cross-linking density and has excellent heat resistance.

Note that the curable resin (A), the curable resin (B1), and the curable compound (B2) each used alone is not preferred because the resulting cured product has low heat resistance. On the other hand, by blending together the curable resin (A) and the curable resin (B1) and/or the curable compound (B2) to be used, the curing reaction sufficiently proceeds, and the resulting cured product not only has excellent heat resistance but also has high dielectric properties that have never been achieved. Moreover, blending together the curable resin (A) and the curable resin (B1) and/or (B2) in a certain mass ratio is preferred because the resulting cured product has more excellent heat resistance and much higher induction properties.

### <Method for Producing Curable Resin (A)>

The curable resin (A) of the present invention is not particularly limited, and can be produced using conventionally known methods as appropriate. For example, it can be obtained by a method of reacting together a phenolic group-containing resin and methacrylic acid, methacrylic anhydride, or methacryloyl chloride in an organic solvent in the presence of an acidic or basic catalyst.

The following describes specific examples of the curable resin (A) of the present invention separately for the curable resin (A1), the curable resin (A2), and the curable resin (A3).

### <Method for Producing Curable Resin (A1)>

First, the following describes a method for producing the curable resin (A1). The curable resin (A1) can be obtained by a method including Step (I-a) and Step (I-b) below, for example.

### <Step (I-a)>

In Step (I-a), an aldehyde compound or a ketone compound shown by General Formulae (12) to (17) below and phenol or a derivative thereof shown by General Formula (18) below are mixed together and reacted in the presence of an acid catalyst to obtain an intermediate phenolic compound as a raw material (precursor) for the curable resin (A1). In General Formulae (12) to (18) below, k represents an integer of 0 to 5, and Ra indicates an alkyl group, an aryl group, an aralkyl group, or a cycloalkyl group with a carbon number of 1 to 12.

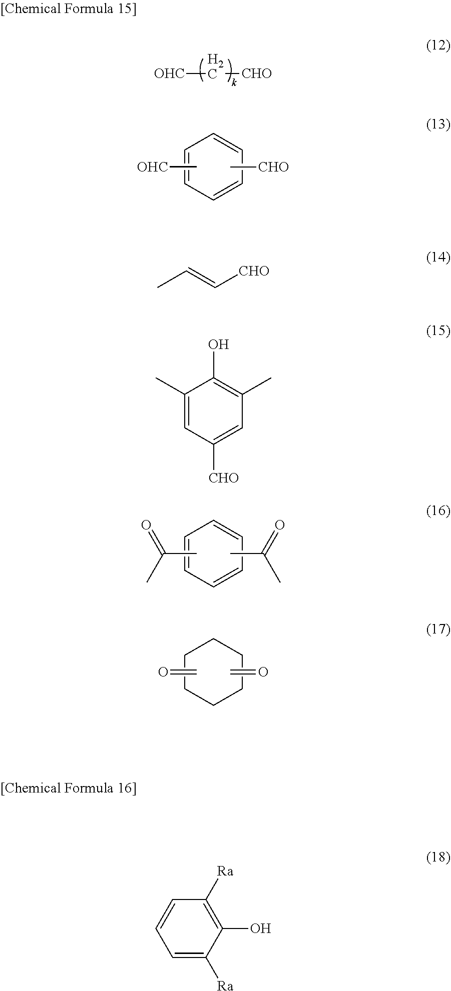

Specific examples of the aldehyde compound or the ketone compound (hereinafter, may be referred to as a “compound (a)”) include, as the aldehyde compound, formaldehyde, acetaldehyde, propionaldehyde, pivaldehyde, butyraldehyde, pentanal, hexanal, trioxane, cyclohexylaldehyde, diphenylacetaldehyde, ethylbutyraldehyde, benzaldehyde, glyoxylic acid, 5-norbornene-2-carboxaldehyde, malondialdehyde, succinedialdehyde, salicylic aldehyde, naphthaldehyde, glyoxal, malondialdehyde, succinaldehyde, glutaraldehyde, crotonaldehyde, and phthalaldehyde. Among the aldehyde compounds, preferred are glyoxal, glutaraldehyde, crotonaldehyde, and phthalaldehyde because of their easy industrial availability. As the ketone compound, cyclohexanedione and diacetylbenzene are preferred, and among these, cyclohexanedione is more preferred in view of its easy industrial availability. Use of the compound (a) is not limited to only one, and two or more can be used in combination.

The phenol or the derivative thereof (hereinafter, may be referred to as a “compound (b)”) is not limited to a particular compound, and specific examples thereof include 2,6-xylenol (2,6-dimethylphenol), 2,3,6-trimethylphenol, 2,6-t-butylphenol, 2,6-diphenylphenol, 2,6-dicyclohexylphenol, and 2,6-diisopropylphenol. The phenol or the derivative thereof may each be used alone, or two or more may be used in combination. Among them, a more preferred mode is use of a compound with alkyl substitution at the ortho position with respect to a phenolic hydroxy group, such as 2,6-xylenol, for example. However, if the steric hindrance is too large, there is a concern that it may hinder reactivity during synthesis of the intermediate phenolic compound, and thus it is preferable to use the compound (b) having a methyl group, an ethyl group, an isopropyl group, a cyclohexyl group, or a benzyl group, for example.

In the method for producing the intermediate phenolic compound for use in the present invention, the compound (a) and the compound (b) are prepared at a molar ratio of the compound (b) with respect to the compound (a) (the compound (b)/the compound (a)) of preferably 0.1 to 10 and more preferably 0.2 to 8 and are reacted in the presence of an acid catalyst, and thereby the intermediate phenolic compound can be obtained.

Examples of the acid catalyst for use in the reaction include inorganic acids such as phosphoric acid, hydrochloric acid, and sulfuric acid; organic acids such as oxalic acid, benzenesulfonic acid, toluenesulfonic acid, methanesulfonic acid, and fluoromethanesulfonic acid; solid acids such as activated white clay, acidic white clay, silica alumina, zeolite, and strongly acidic ion exchange resins; and heteropolyacids. Preferably used are inorganic acids, oxalic acid, benzenesulfonic acid, toluenesulfonic acid, methanesulfonic acid, and fluoromethanesulfonic acid, which are homogeneous catalysts that can be easily removed after the reaction by neutralization with a base and washing with water.

As to the blending amount of the acid catalyst, the acid catalyst is blended in a range of 0.001 to 40 parts by mass with respect to 100 parts by mass of the total amount of the compound (a) and the compound (b) as the raw materials to be prepared first. From the viewpoints of handleability and economy, the amount is preferably 0.001 to 25 parts by mass.

It suffices if the reaction temperature is normally in a range of 30 to 150° C., and is preferably 60 to 120° C. in order to inhibit the formation of isomeric structures, avoid side reactions such as thermal decomposition, and obtain a highly pure intermediate phenolic compound.

The reaction time is usually in a range of a total of 0.5 to 24 hours and preferably in a range of a total of 0.5 to 15 hours under the reaction temperature condition because the reaction does not proceed completely in a short time, whereas side reactions such as a thermal decomposition reaction of the product occur in a long time.

In the method for producing the intermediate phenolic compound, although other solvents are not necessarily required to be used because the phenol or the derivative thereof also serves as a solvent, solvents can be used.

Examples of an organic solvent used for synthesizing the intermediate phenolic compound include ketones such as acetone, methyl ethyl ketone (MEK), methyl isobutyl ketone, cyclohexanone, and acetophenone; alcohols such as 2-ethoxyethanol, methanol, and isopropyl alcohol; aprotic solvents such as N,N-dimethylformamide, N,N-dimethylacetamide, dimethyl sulfoxide, N-methyl-2-pyrrolidone, acetonitrile, and sulfolane; cyclic ethers such as dioxane and tetrahydrofuran; esters such as ethyl acetate and butyl acetate; aromatic solvents such as benzene, toluene, and xylene. These may be used alone or used by being mixed together.

The hydroxy group equivalent (the phenol equivalent) of the intermediate phenolic compound is preferably 80 to 500 g/eq and more preferably 100 to 300 g/eq from the viewpoint of heat resistance. The hydroxy group equivalent (the phenol equivalent) of the intermediate phenolic compound is calculated by the titration method, which refers to the neutralization titration method conforming to JIS K0070.

### <Step (I-b)>

In Step (I-b), the curable resin (A1) can be obtained by known methods such as a reaction of the intermediate phenolic compound with methacrylic anhydride and methacryloyl chloride in the presence of a basic or acidic catalyst.

Methacrylic anhydride and methacryloyl chloride may each be used alone or used by being mixed together.

Specific examples of the basic catalyst include dimethylaminopyridine, tetrabutylammonium chloride (TBAB), alkaline earth metal hydroxides, alkali metal carbonates, and alkali metal hydroxides. Specific examples of the acidic catalyst include sulfuric acid and methanesulfonic acid. Dimethylaminopyridine is particularly superior in terms of catalytic activity.

Examples of the reaction of the intermediate phenolic compound and methacrylic anhydride include a method in which 1 to 10 moles of methacrylic anhydride is added per 1 mole of hydroxy groups contained in the intermediate phenolic compound and reacted at a temperature of 30 to 150° C. for 1 to 40 hours while 0.01 to 0.2 mole of the basic catalyst is added at once or added gradually.

The reaction rate in the synthesis of the curable resin (A1) can be increased by using an organic solvent in combination during the reaction with methacrylic anhydride (introduction of the cross-linking group). Such an organic solvent is not limited to a particular organic solvent. Examples thereof include ketones such as acetone and methyl ethyl ketone (MEK); alcohols such as methanol, ethanol, 1-propyl alcohol, isopropyl alcohol, 1-butanol, secondary butanol, and tertiary butanol, cellosolves such as methyl cellosolve and ethyl cellosolve; ethers such as tetrahydrofuran, 1,4-dioxane, 1,3-dioxane, and diethoxyethane; aprotic polar solvents such as acetonitrile, dimethyl sulfoxide, and dimethylformamide; and toluene. These organic solvents may each be used alone, or two or more may be used in combination as appropriate in order to prepare polarity.

After the end of the reaction with methacrylic anhydride or the like described above (introduction of the cross-linking group), the reaction product is reprecipitated in a poor solvent, then the precipitate is stirred in the poor solvent at a temperature of 20 to 100° C. for 0.1 to 5 hours and is filtered under reduced pressure, then the precipitate is dried at a temperature of 40 to 80° C. for 1 to 10 hours, and thereby the desired curable resin (A1) can be obtained. Examples of the poor solvent include hexane.

### <Method for Producing Curable Resin (A2)>

Next, the following describes a method for producing the curable resin (A2). The curable resin (A2) can be obtained by, for example, a method of reaction in an organic solvent such as an interfacial polymerization method, a method of reaction in a molten state such as melt polymerization, or the like.

### <Interfacial Polymerization Method>

Examples of the interfacial polymerization method include a method of mixing a solution (an organic phase) in which a divalent carboxylic acid halide and a cross-linking group introducing agent used to introduce a reactive group (a cross-linking group) as a terminal structure are dissolved in an organic solvent incompatible with water with an aqueous alkaline solution (an aqueous phase) containing a divalent phenol, a polymerization catalyst, and an antioxidant and performing a polymerization reaction while stirring them at a temperature of 50° C. or lower for 1 to 8 hours.

Examples of another interfacial polymerization method include a method of blowing phosgene into a mixture of a solution (an organic phase) in which a cross-linking group introducing agent used to introduce a reactive group (a cross-linking group) as a terminal structure is dissolved in an organic solvent incompatible with water and an aqueous alkaline solution (an aqueous phase) containing a divalent phenol, a polymerization catalyst, and an antioxidant and performing a polymerization reaction while stirring them at a temperature of 50° C. or lower for 1 to 8 hours.

The organic solvent for use in the organic phase is preferably a solvent that is incompatible with water and dissolves polyarylate. Examples of such a solvent include chlorinated solvents such as methylene chloride, 1,2-dichloroethane, chloroform, carbon tetrachloride, chlorobenzene, 1,1,2,2-tetrachloroethane, 1,1,1-trichloroethane, and o-, m-, p-dichlorobenzene, aromatic hydrocarbons such as toluene, benzene, and xylene, and tetrahydrofuran. Methylene chloride is preferred because of its ease of use in production.

Examples of the aqueous alkaline solution for use in the aqueous phase include an aqueous solution of sodium hydroxide and an aqueous solutions of potassium hydroxide.

The antioxidant is used in order to prevent oxidation of the divalent phenol component. Examples of the antioxidant include sodium hydrosulfite, L-ascorbic acid, erythorbic acid, catechin, tocopherol, and butylated hydroxyanisole. Among them, sodium hydrosulfite is preferred because of its excellent water solubility.

Examples of the polymerization catalyst include quaternary ammonium salts such as tri-n-butylbenzylammonium halides, tetra-n-butylammonium halides, trimethylbenzylammonium halides, and triethylbenzylammonium halides; and quaternary phosphonium salts such as tri-n-butylbenzylphosphonium halides, tetra-n-butylphosphonium halides, trimethylbenzylphosphonium halides, and triethylbenzylphosphonium halides. Among them, preferred are tri-n-butylbenzylammonium halides, trimethylbenzylammonium halides, tetra-n-butylammonium halides, tri-n-butylbenzylphosphonium halides, and tetra-n butylphosphonium halides because they have high molecular weights and can obtain polymers with low acid values.

The amount of the polymerization catalyst added is preferably 0.01 to 5.0 mol % and more preferably 0.1 to 1.0 mol % with respect to the number of moles of the divalent phenol used for polymerization. The amount of the polymerization catalyst added is 0.01 mol % or more is preferred because it allows the effect of the polymerization catalyst to be obtained, and increases the molecular weight of the polyarylate resin. On the other hand, the amount being 5.0 mol % or less is preferred because it inhibits the hydrolysis reaction of divalent aromatic carboxylic acid halides, and the molecular weight of the polyarylate resin is higher.

Examples of the divalent phenol include 2,2-bis(4-hydroxy-3,5-dimethylphenyl)propane, 2,2-bis(4-hydroxy-3,6-dimethylphenyl)propane, 2,2-bis(3-methyl-4-hydroxyphenyl)propane, 2,2-bis(4-hydroxy-3,5,6-trimethylphenyl)propane, 2,2-bis(4-hydroxy-2,3,6-trimethylphenyl)propane, bis(4-hydroxy-3,5-dimethylphenyl)methane, bis(4-hydroxy-3,6-dimethylphenyl)methane, bis(4-hydroxy-3-methylphenyl)methane, bis(4-hydroxy-3,5,6-trimethylphenyl)methane, bis(4-hydroxy-2,3,6-trimethylphenyl)methane, 1,1-bis(4-hydroxy-3,5-dimethylphenyl)-1-phenylethane, 2,2-bis(4-hydroxy-3,5-dimethylphenyl)butane, bis(4-hydroxy-3,5-dimethylphenyl)diphenylmethane, 2,2-bis(4-hydroxy-3-isopropylphenyl)propane, 1,1-bis(4-hydroxy-3,5-dimethylphenyl)ethane, 1,3-bis(2-(4-hydroxy-3,5-dimethylphenyl)-2-propyl)benzene, 1,4-bis(2-(4-hydroxy-3,5-dimethylphenyl)-2-propyl)benzene, 1,1-bis(4-hydroxy-3,5-dimethylphenyl)-3,3,5-trimethylcyclohexane, 1,1-bis(4 hydroxy-3,5-dimethylphenyl)cyclohexane, 2,2-bis(2-hydroxy-5-biphenylyl)propane, and 2,2-bis(4-hydroxy-3-cyclohexyl-6-methylphenyl)propane.

Examples of the divalent carboxylic acid halide include terephthaloyl halides, isophthaloyl halides, orthophthaloyl halides, diphenoyl halides, biphenyl-4,4′-dicarboxylic acid halides, 1,4-naphthalenedicarboxylic acid halides, 2,3-naphthalenedicarboxylic acid halides, 2,6-naphthalenedicarboxylic acid halides, 2,7-naphthalenedicarboxylic acid halides, 1,8-naphthalenedicarboxylic acid halides, 1,5-naphthalenedicarboxylic acid halides, diphenyl ether-2,2′-dicarboxylic acid halides, diphenyl ether-2,3′-dicarboxylic acid halides, diphenyl ether-2,4′-dicarboxylic acid halides, diphenyl ether-3,3′-dicarboxylic acid halides, diphenyl ether-3,4′-dicarboxylic acid halides, diphenyl ether-4,4′-dicarboxylic acid halides, 1,4-cyclohexanedicarboxylic acid halides, and 1,3-cyclohexanedicarboxylic acid halides.

The end structure (General Formula (A2b)) of the curable resin (A2) has a methacryloyloxy group, in which a cross-linking group introducing agent can be used in order to introduce the cross-linking group (the methacryloyloxy group). For example, methacrylic anhydride, methacryloyl chloride, or the like can be reacted as the cross-linking group introducing agent. By reacting together these compounds, a cross-linking group can be introduced to the curable resin, and thermosetting with a low dielectric constant and a low dielectric loss tangent is achieved, and provides a preferred mode.

Methacrylic anhydride and methacryloyl chloride may each be used alone or used by being mixed together.

### <Melt Polymerization Method>

Examples of the melt polymerization method include a method of acetylating a raw material divalent phenol and then performing deacetic acid polymerization of the acetylated divalent phenol and a divalent carboxylic acid and a method of performing an ester exchange reaction of a divalent phenol and a carbonate.

In the acetylation reaction, an aromatic dicarboxylic acid component, a divalent phenol component, and acetic anhydride are fed into a reaction vessel. Then, nitrogen purging is performed, and the mixture is stirred in an inert atmosphere, at a temperature of 100 to 240° C. and preferably 120 to 180° C., for 5 minutes to 8 hours and preferably 30 minutes to 5 hours, under normal pressure or pressurized pressure. The molar ratio of acetic anhydride to the hydroxy group of the divalent phenol component is preferably 1.00 to 1.20.

The deacetic acid polymerization reaction is a reaction reacting the acetylated divalent phenol and the divalent carboxylic acid to subject them to polycondensation. In the deacetic acid polymerization reaction, the temperature is maintained at 240° C. or higher, preferably 260° C. or higher, and more preferably 220° C. or higher for 30 minutes or longer at a degree of depressurization of 500 Pa or lower, preferably 260 Pa or lower, and more preferably 130 Pa or lower with stirring. When the temperature is 240° C. or higher, when the degree of depressurization is 500 Pa or lower, or when the holding time is 30 minutes or longer, the deacetic acid reaction sufficiently proceeds to reduce the amount of acetic acid in the obtained polyarylate resin, shorten the overall polymerization time, and prevent deterioration of polymer color tone.

In the acetylation reaction and the deacetic acid polymerization reaction, it is preferable to use a catalyst as needed. Examples of the catalyst include organotitanate compounds such as tetrabutyl titanate; alkali metal salts such as zinc acetate and potassium acetate; alkaline earth metal salts such as magnesium acetate; antimony trioxide; organotin compounds such as hydroxybutyl tin oxide and tin octylate; and heterocyclic compounds such as N-methylimidazole. The amount of the catalyst added is usually 1.0 mol % or less, more preferably 0.5 mol % or less, and even more preferably 0.2 mol % or less with respect to the total monomer component of the obtained polyarylate resin.

In the ester exchange reaction, the reaction is carried out at a temperature of 120 to 260° C. and preferably 160 to 200° C. for 0.1 to 5 hours and preferably 0.5 to 6 hours at a pressure of normal pressure to 1 Torr.

As the catalyst for the ester exchange reaction, salts of zinc, tin, zirconium, and lead are preferably used, for example, which can be used alone or in combination. Specific examples of the ester exchange reaction catalyst include zinc acetate, zinc benzoate, zinc 2-ethyl hexanoate, tin(II) chloride, tin(IV) chloride, tin(II) acetate, tin(IV) acetate, dibutyl tin dilaurate, dibutyl tin oxide, dibutyl tin dimethoxide, zirconium acetylacetonate, zirconium oxyacetate, zirconium tetrabutoxide, lead(II) acetate, and lead(IV) acetate. These catalysts are used at a ratio of 0.000001 to 0.1 mol % and preferably 0.00001 to 0.01 mol % with respect to a total of 1 mol of the divalent phenol.

As the divalent phenol, the divalent phenol in the interfacial polymerization method described above can be used in the same manner.

Examples of the divalent carboxylic acid include terephthalic acid, isophthalic acid, orthophthalic acid, diphenic acid, biphenyl-4,4′-dicarboxylic acid, 1,4-naphthalenedicarboxylic acid, 2,3-naphthalenedicarboxylic acid, 2,6-naphthalenedicarboxylic acid, 2,7-naphthalenedicarboxylic acid, 1,8-naphthalenedicarboxylic acid, 1,5-naphthalenedicarboxylic acid, diphenyl ether-2,2′-dicarboxylic acid, diphenyl ether-2,3′-dicarboxylic acid, diphenyl ether-2,4′-dicarboxylic acid, diphenyl ether-3,3′-dicarboxylic acid, diphenyl ether-3,4′-dicarboxylic acid, diphenyl ether-4,4′-dicarboxylic acid, 1,4 cyclohexanedicarboxylic acid, and 1,3-cyclohexanedicarboxylic acid.

Examples of the carbonate include diphenyl carbonate, ditolyl carbonate, bis(chlorophenyl) carbonate, m-cresol carbonate, dinaphthyl carbonate, bis(diphenyl) carbonate, diethyl carbonate, dimethyl carbonate, dibutyl carbonate, and dicyclohexyl carbonate.

The end structure (General Formula (A2b)) of the curable resin (A2) has a methacryloyloxy group, in which a cross-linking group introducing agent can be used in order to introduce the cross-linking group (the methacryloyloxy group). As the cross-linking group introducing agent, the cross-linking group introducing agent in the interface polymerization method described above can be used in the same manner.

### <Method for Producing Curable Resin (A3)>

Finally, the following describes a method for producing the curable resin (A3). The curable resin (A3) can be obtained by a method including Step (II-a) and Step (II-b) below, for example.

### <Step (II-a)>

In Step (II-a), a compound of General Formula (19) below and a compound of any of General Formulae (22-1) to (22-3) below are reacted in the presence of an acid catalyst to obtain an intermediate phenolic compound as a raw material (precursor) for the curable resin (A3). In General Formula (19) below, Rcs each independently indicate a monovalent functional group selected from the group consisting of General Formulae (20) and (21) below, in which the ortho-position of at least one of the two Rcs is a hydrogen atom, Rb represents an alkyl group, an aryl group, an aralkyl group, or a cycloalkyl group with a carbon number of 1 to 12, and 1 indicates an integer of 0 to 4.

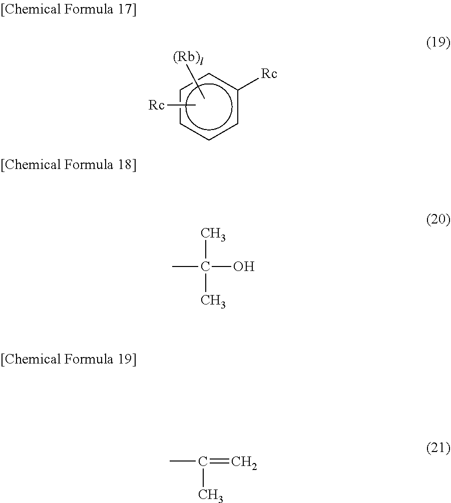

General Formula (22-1) below is the case in which j in General Formula (1) above is 0, that is, the curable resin having an indane skeleton is a benzene ring, in which i is preferably 1 or 2, and i is more preferably 1. General Formula (22-2) below is the case in which j in General Formula (1) above is 1, that is, the curable resin having an indane skeleton is a naphthalene ring, in which i is preferably 1 or 2 and more preferably 1. General Formula (22-3) below is the case in which j in General Formula (1) above is 2, that is, the curable resin having an indane skeleton is an anthracene ring, in which i is preferably 1 or 2 and more preferably 1. By the curable resin with an indane skeleton having a hydroxy group (a phenolic hydroxy group), a phenolic hydroxy group can be introduced to the end of the structure, which is a preferred mode. Ra and h, each of which indicates the same as above, are phenol or a derivative thereof, and by reacting the compound of General Formula (19) above and a compound of any of General Formulae (22-1) to (22-3) below in the presence of an acid catalyst, an intermediate phenolic compound indicated by General Formula (23) below can be obtained. The letters Ra, h, and i in General Formula (23) below indicate the same as above, and n indicates a repeating unit. General Formula (23) below exemplifies the case in which j in General Formula (1) above is 0, that is, the curable resin having an indane skeleton is a benzene ring.

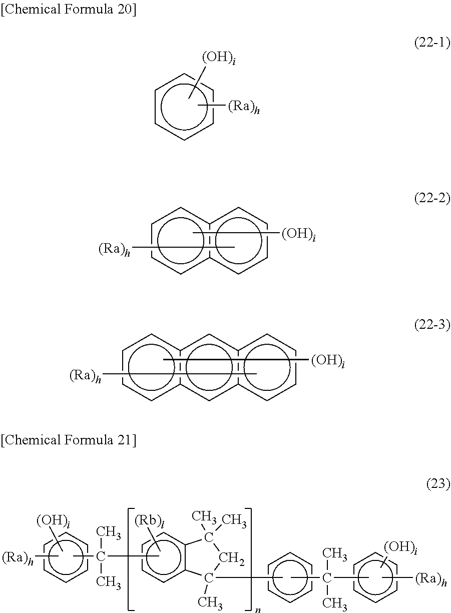

General Formula (23) has a weight average molecular weight (Mw) of preferably 500 to 50,000, more preferably 1,000 to 10,000, and even more preferably 1,500 to 5,000. Being within the above range improves solvent solubility is preferred because it makes processing workability favorable, and further provides the resulting cured product with excellent bendability and flexibility.

The compound represented by General Formula (19) above used in the present invention (hereinafter, a “compound (c)”) is not limited to a particular compound, and typically used is p- and m-diisopropenylbenzene, p- and m-bis(α-hydroxyisopropyl)benzene (α,α′-dihydroxy-1,3-diisopropylbenzene), p- and m-bis(α-chloroisopropyl)benzene, 1-(α-hydroxyisopropyl)-3-isopropenylbenzene, 1-(α-hydroxyisopropyl)-4-isopropenylbenzene, or a mixture thereof. Nuclear alkyl substituents of these compounds such as diisopropenyl toluene and bis(α-hydroxyisopropyl)toluene can also be used, and in addition, nuclear halogen substituents such as chloro-diisopropenyl benzene and chlorobis(α-hydroxyisopropyl)benzene can also be used.

Other examples of the compound (c) include 2-chloro-1,4-diisopropenylbenzene, 2-chloro-1,4-bis(α-hydroxyisopropyl)benzene, 2-bromo-1,4-diisopropenylbenzene, 2-bromo-1,4-bis(α-hydroxyisopropyl)benzene, 2-bromo-1,3-diisopropenylbenzene, 2-bromo-1,3-bis(α-hydroxyisopropyl)benzene, 4-bromo-1,3-diisopropylbenzene, 4-bromo-1,3-bis(α-hydroxyisopropyl)benzene, 5-bromo-1,3 diisopropenylbenzene, 5-bromo-1,3-bis(α-hydroxyisopropyl)benzene, 2-methoxy-1,4-diisopropenylbenzene, 2-methoxy-1,4-bis(α-hydroxyisopropyl)benzene, 5-ethoxy-1,3-diisopropenylbenzene, 5-ethoxy-1,3-bis(α-hydroxyisopropyl)benzene, 2-phenoxy-1,4-diisopropenylbenzene, 2-phenoxy-1,4-bis(α-hydroxyisopropyl)benzene, 2,4-diisopropenylbenzenethiol, 2,4-bis(α-hydroxyisopropyl)benzenethiol, 2,5-diisopropenylbenzenethiol, 2,5-bis(α-hydroxyisopropyl)benzenethiol, 2-methylthio-1,4-diisopropenylbenzene, 2-methylthio-1,4-bis(α-hydroxyisopropyl)benzene, 2-phenylthio-1,3-diisopropenylbenzene, 2-phenylthio-1,3-bis(α-hydroxyisopropyl)benzene, 2-phenyl-1,4-diisopropenylbenzene, 2-phenyl-1,4-bis(α-hydroxyisopropyl)benzene, 2-cyclopentyl-1,4-diisopropenylbenzene, 2-cyclopentyl-1,4-bis(α-hydroxyisopropyl)benzene, 5-naphthyl-1,3-diisopropenylbenzene, 5-naphthyl-1,3-bis(α-hydroxyisopropyl)benzene, 2-methyl-1,4-diisopropenylbenzene 2-methyl-1,4-bis(α-hydroxyisopropyl)benzene, 5-butyl-1,3-diisopropenylbenzene, 5-butyl-1,3-bis(α-hydroxyisopropyl)benzene, 5-cyclohexyl-1,3-diisopropenylbenzene, and 5-cyclohexyl-1,3-bis(α-hydroxyisopropyl)benzene.

Note that the substituent contained in the compound (c) is not limited to a particular substituent, and the exemplified compounds can be used, but in the case of substituents with large steric hindrance, compared to substituents with small steric hindrance, stacking of the resulting intermediate phenolic compound is less likely to occur, and crystallization of the intermediate phenolic compound is less likely to occur. That is, the solvent solubility of the intermediate phenolic compound improves, and a preferred mode is provided.

The compound represented by any of General Formulae (22-1) to (22-3) above (hereinafter, a “compound (d)”) is phenol or a derivative thereof and is not limited to a particular compound. Typical examples thereof include 2,6-xylenol (2,6-dimethylphenol), 2,3,6-trimethylphenol, 2,6-t-butylphenol, 2,6-diphenylphenol, 2,6-dicyclohexylphenol, and 2,6-diisopropylphenol. The phenol or the derivative thereof may each be used alone, or two or more may be used in combination. Among them, a more preferred mode is use of a compound with alkyl substitution at the ortho position with respect to a phenolic hydroxy group, such as 2,6-xylenol, for example. However, if the steric hindrance is too large, there is a concern that it may hinder reactivity during synthesis of the intermediate phenolic compound, and thus it is preferable to use the compound (d) having a methyl group, an ethyl group, an isopropyl group, a cyclohexyl group, or a benzyl group, for example.

In the method for producing the intermediate phenolic compound represented by General Formula (23) above used in the present invention, the compound (c) and the compound (d) are prepared at a molar ratio of the compound (d) with respect to the compound (c) (the compound (d)/the compound (c)) of preferably 0.1 to 10 and more preferably 0.2 to 8 and are reacted in the presence of an acid catalyst, and thereby the intermediate phenolic compound having an indane skeleton can be obtained.

Examples of the acid catalyst for use in the reaction include inorganic acids such as phosphoric acid, hydrochloric acid, and sulfuric acid; organic acids such as oxalic acid, benzenesulfonic acid, toluenesulfonic acid, methanesulfonic acid, and fluoromethanesulfonic acid; solid acids such as activated white clay, acidic white clay, silica alumina, zeolite, and strongly acidic ion exchange resins; and heteropoly hydrochloric acids. Preferably used are oxalic acid, benzenesulfonic acid, toluenesulfonic acid, methanesulfonic acid, and fluoromethanesulfonic acid, which are homogeneous catalysts that can be easily removed after the reaction by neutralization with a base and washing with water.

As to the blending amount of the acid catalyst, the acid catalyst is blended in a range of 0.001 to 40 parts by mass with respect to 100 parts by mass of the total amount of the compound (c) and the compound (d) as the raw materials to be prepared first. From the viewpoints of handleability and economy, the amount is preferably 0.001 to 25 parts by mass.

The reaction temperature may be normally in a range of 50 to 300° C. and is preferably 80 to 200° C. in order to inhibit the formation of isomeric structures, avoid side reactions such as thermal decomposition, and obtain a highly pure intermediate phenolic compound.

The reaction time is usually in a range of a total of 0.5 to 24 hours and preferably in a range of a total of 0.5 to 12 hours under the reaction temperature condition because the reaction does not proceed completely in a short time, whereas side reactions such as a thermal decomposition reaction of the product occur in a long time.

In the method for producing the intermediate phenolic compound, although other solvents are not necessarily required to be used because the phenol or the derivative thereof also serves as a solvent, solvents can be used. For example, in the case of a reaction system that also serves as a dehydration reaction, specifically, when a compound having an α-hydroxypropyl group is used as a raw material for the reaction, a method of completing the dehydration reaction using an azeotropically dehydratable solvent such as toluene, xylene, or chlorobenzene, then distilling off the solvent, and conducting the reaction within the above reaction temperature range may be employed.

Examples of an organic solvent used for synthesizing the intermediate phenolic compound include ketones such as acetone, methyl ethyl ketone (MEK), methyl isobutyl ketone, cyclohexanone, and acetophenone; aprotic solvents such as N,N-dimethylformamide, N,N-dimethylacetamide, dimethyl sulfoxide, N-methyl-2-pyrrolidone, acetonitrile, and sulfolane; cyclic ethers such as dioxane and tetrahydrofuran; esters such as ethyl acetate and butyl acetate; and aromatic solvents such as benzene, toluene, and xylene. These may be used alone or used by being mixed together.

The hydroxy group equivalent (the phenol equivalent) of the intermediate phenolic compound is preferably 200 to 2,000 g/eq and more preferably 220 to 500 g/eq from the viewpoint of heat resistance. The hydroxy group equivalent (the phenol equivalent) of the intermediate phenolic compound is calculated by the titration method, which refers to the neutralization titration method conforming to JIS K0070.

### <Step (II-b)>

In Step (II-b), the curable resin (A3) can be obtained by a known method such as a reaction of the intermediate phenolic compound and methacrylic anhydride or methacryloyl chloride in the presence of a basic or acidic catalyst.

Methacrylic anhydride and methacryloyl chloride may each be used alone or used by being mixed together.

Specific examples of the basic catalyst include dimethylaminopyridine, alkaline earth metal hydroxides, alkali metal carbonates, and alkali metal hydroxides. Specific examples of the acidic catalyst include sulfuric acid and methanesulfonic acid. Dimethylaminopyridine is particularly superior in terms of catalytic activity.

Examples of the reaction of the intermediate phenolic compound and methacrylic anhydride include a method in which 1 to 5 moles of methacrylic anhydride is added per 1 mole of hydroxy groups contained in the intermediate phenolic compound and reacted at a temperature of 30 to 150° C. for 1 to 40 hours while 0.03 to 1 mole of the basic catalyst is added at once or added gradually.

The reaction rate in the synthesis of the curable resin having an indane skeleton can be increased by using an organic solvent in combination during the reaction with methacrylic anhydride. Such an organic solvent is not limited to a particular organic solvent. Examples thereof include ketones such as acetone and methyl ethyl ketone; alcohols such as methanol, ethanol, 1-propyl alcohol, isopropyl alcohol, 1-butanol, secondary butanol, and tertiary butanol, cellosolves such as methyl cellosolve and ethyl cellosolve; ethers such as tetrahydrofuran, 1,4-dioxane, 1,3-dioxane, and diethoxyethane; aprotic polar solvents such as acetonitrile, dimethyl sulfoxide, and dimethylformamide; and toluene. These organic solvents may each be used alone, or two or more may be used in combination as appropriate in order to prepare polarity.

After the end of the above reaction with methacrylic anhydride, the reaction product is washed with water, and then unreacted methacrylic anhydride and used organic solvents in combination are distilled off under a heated and reduced pressure condition. Furthermore, to further reduce hydrolyzable halogens in the resulting curable resin having an indane skeleton, by dissolving the curable resin having an indane skeleton again in an organic solvent such as toluene, methyl isobutyl ketone, or methyl ethyl ketone and adding an aqueous solution of an alkali metal hydroxide such as sodium hydroxide or potassium hydroxide thereto, the reaction can be further conducted. In this process, a correlation transfer catalyst such as a quaternary ammonium salt or a crown ether may be present for the purpose of increasing the reaction rate. When the correlation transfer catalyst is used, its use amount is preferably in a range of 0.1 to 10% by mass with respect to the curable resin having an indane skeleton to be used. After the end of the reaction, the formed salts are removed by filtration, washing with water, or the like, and the organic solvent is distilled off under a heated and reduced pressure condition to obtain an objective curable resin having an indane skeleton with a low hydrolyzable chlorine content.

### <Method for Producing Curable Resin (B1)>

The curable resin (B1) of the present invention can be produced using conventionally known methods as appropriate without particular limitations. Examples of one embodiment of the method for producing the curable resin (B1) of the present invention include a multifunctional vinyl aromatic copolymer in which a divinyl aromatic compound and a monovinyl aromatic compound are polymerized in an organic solvent in the presence of a Lewis acid catalyst.

### <Curable Resin Composition>

The curable resin composition of the present invention contains the curable resin (A) and the curable resin (B1) and/or the curable compound (B2). When the curable resin (A), the curable resin (B1), and the curable compound (B2) are each used alone, the resulting cured product has low heat resistance, which is not preferred. On the other hand, by blending together the curable resin (A) and the curable resin (B1) and/or the curable compound (B2) to be used, the curing reaction sufficiently proceeds, and the resulting cured product not only has excellent heat resistance but also has high dielectric properties that have never been achieved. Moreover, blending together the curable resin (A) and the curable resin (B1) and/or the curable compound (B2) in a certain mass ratio is preferred because the resulting cured product has more excellent heat resistance and much higher induction properties.

### [Other Resins and Others]

The curable resin composition of the present invention may be blended with thermoplastic resins as needed to the extent that the purpose is not impaired. Examples thereof include styrene-butadiene resins, styrene-butadiene-styrene block resins, styrene-isoprene-styrene resins, styrene-maleic anhydride resins, acrylonitrile butadiene resins, polybutadiene resins and their hydrogenated resins, acrylic resins, and silicone resins. By using the thermoplastic resins, properties caused by the resins can be imparted to the cured product, and a preferred mode is provided. As the properties that can be imparted, they can contribute to imparting formability, high-frequency properties, conductor adhesiveness, soldering heat resistance, adjustment of glass transition temperature, the coefficient of thermal expansion, and smear removability, for example.

### [Flame Retardant]

The curable resin composition of the present invention can be blended with non-halogenated flame retardants containing substantially no halogen atoms in order to exhibit flame retardancy as needed. Examples of the non-halogenated flame retardants include phosphorus-based flame retardants, nitrogen-based flame retardants, silicone-based flame retardants, inorganic flame retardants, and organometallic salt-based flame retardants, and these may be used alone, or two or more may be used in combination.

### [Inorganic Filler]

The curable resin composition of the present invention can be blended with inorganic fillers as needed. Examples of the inorganic fillers include fused silica, crystalline silica, alumina, silicon nitride, and aluminum hydroxide. When the blending amount of the inorganic fillers is made especially large, fused silica is preferably used. For the fused silica, although both crushed one and spherical one can be used, it is preferable to use mainly the spherical one in order to increase the blending amount of the fused silica and to inhibit an increase in the melt viscosity of the molding material. To further increase the blending amount of the spherical silica, the particle size distribution of the spherical silica is preferably appropriately adjusted.

### <Other Compounding Agents>

Various compounding agents such as silane coupling agents, mold release agents, pigments, and emulsifiers can be added to the curable resin composition of the present invention as needed.

### <Cured Product>

The present invention relates to a cured product obtained by subjecting the curable resin composition to a curing reaction. The curable resin composition is obtained by uniformly mixing together the curable resin (A), the curable resin (B1), and the curable compound (B2), and in addition, the components such as the flame retardants described above and can be easily made into a cured product by the same method as conventionally known methods. Examples of the cured product include molded cured products such as laminates, cast products, adhesive layers, coatings, and films.

Examples of the curing reaction include heat curing and ultraviolet curing reactions, among which the heat curing reaction is easily carried out under a non-catalyst condition.

### <Uses>

The cured product obtained by the curable resin composition of the present invention has excellent heat resistance and dielectric properties and can thus suitably be used for heat-resistant members and electronic members. It can be particularly suitably used for varnishes for use in the manufacture of prepregs, circuit boards, semiconductor sealing materials, semiconductor devices, build-up films, build-up boards, adhesives, and resist materials. It can also be suitably used for matrix resins of fiber-reinforced resins and is particularly suitable as prepregs with high heat resistance. The thus obtained heat-resistant members and electronic members can be suitably used for various uses including, but not limited to, industrial machine parts, general machine parts, parts for automobiles, railways, vehicles, and the like, space and aviation-related parts, electronic and electric parts, construction materials, container and packaging members, household goods, sports and leisure goods, and housing members for wind power generation.

The following describes representative products manufactured using the curable resin composition of the present invention with reference to examples.

### <Varnish>

The present invention relates to a varnish obtained by diluting the curable resin composition with an organic solvent. As the method for preparing the varnish, known methods can be used, and it can be made into a resin varnish with the curable resin composition dissolved (diluted) in an organic solvent.

Examples of the organic solvent include toluene, xylene, N,N-dimethylformamide, N,N-dimethylacetamide, N-methyl-2-pyrrolidone, methyl ethyl ketone (MEK), methyl isobutyl ketone, dioxane, and tetrahydrofuran, which can be used alone or as a mixed solvent of two or more.

### <Prepreg>

The present invention relates to a prepreg having a reinforcing base material and semi-curing of the varnish impregnated into the reinforcing base material. The varnish (resin varnish) is impregnated into the reinforcing base material, and the reinforcing base material impregnated with the varnish (resin varnish) is subjected to heat treatment to make the curable resin composition semi-cured (or uncured), and thus the prepreg can be made.

Examples of the reinforcing base material into which the varnish (resin varnish) is impregnated include woven and non-woven fabrics, mats, and paper made of inorganic fibers and organic fibers such as glass fibers, polyester fibers, and polyamide fibers, which can be used alone or in combination.

The mass ratio of the curable resin composition and the reinforcing base material in the prepreg, which is not limited to a particular ratio, is usually preferable to prepare (the resin content in) the curable resin composition in the prepreg to be 20 to 60% by mass.

The conditions for the heat treatment for the prepreg are selected as appropriate in accordance with the types and amounts of organic solvents, catalysts, and various additives used. It is usually performed under conditions including 3 to 30 minutes at a temperature of 80 to 220° C.

### <Circuit Board>

The present invention relates to a circuit board obtained by laminating and thermocompression molding the prepreg and copper foil to each other. Specifically, as the method for obtaining a circuit board from the curable resin composition of the present invention, the prepregs are laminated on each other in a usual way, the copper foil is overlaid thereon as appropriate, and they are thermocompression molded to each other under a pressure of 1 to 10 MPa at 170 to 300° C. for 10 minutes to 3 hours to make the circuit board.

### <Semiconductor Sealing Material>

The semiconductor sealing material preferably contains the curable resin composition. Specifically, examples of the method for obtaining the semiconductor sealing material from the curable resin composition of the present invention include a method of thoroughly melting and mixing compounding agents such as inorganic fillers as optional components into the curable resin composition until they become uniform using an extruder, a kneader, a roll, or the like as needed. In such a case, fused silica is usually used as the inorganic filler. When used as a high thermal conductivity semiconductor sealing material for power transistors and power ICs, crystalline silica, alumina, silicon nitride, or the like, which has higher thermal conductivity than fused silica, may be used. As its filling ratio, the inorganic filler is preferably used in a range of 30 to 95 parts by mass with respect to 100 parts by mass of the curable resin composition. In particular, to improve flame retardancy, moisture resistance, and solder cracking resistance and to lower the coefficient of linear expansion, it is more preferably 70 parts by mass or more and even more preferably 80 parts by mass or more.

### <Semiconductor Device>

The semiconductor device preferably includes a cured product obtained by heating and curing the semiconductor sealing material. Specifically, examples of semiconductor package molding to obtain the semiconductor device from the curable resin composition of the present invention include a method of molding the semiconductor sealing material by pouring or using a transfer molding machine, an injection molding machine, or the like and further heating and curing it at 50 to 250° C. for 2 to 10 hours.

### <Build-Up Board>

Examples of the method for obtaining a build-up board from the curable resin composition of the present invention include a method passing through Steps 1 to 3. In Step 1, the curable resin composition, which is blended with rubber, fillers, or the like as appropriate, is first applied to a circuit board formed with a circuit using spray coating, curtain coating, or the like and is then cured. In Step 2, as needed, after drilling a certain through hole part or the like in the circuit board to which the curable resin composition has been applied, the circuit board is treated with a roughening agent and its surface is rinsed with hot water to form unevenness on the board, which is then plated with metal such as copper. In Step 3, the operations of Steps 1 and 2 are sequentially repeated as desired to alternately build up a resin insulation layer and a conductor layer with a certain circuit pattern to form a build-up board. In the above step, drilling of the through hole part may be performed after the formation of the outermost resin insulating layer. In the build-up board in the present invention, the build-up board can also be produced by thermocompression molding copper foil with a resin, in which the resin composition is semi-cured on copper foil, onto a wiring board formed with a circuit at 170 to 300° C. to form a roughened surface, with the plating step omitted.

### <Build-Up Film>

The build-up film preferably contains the curable resin composition. Examples of the method for obtaining the build-up film from the curable resin composition of the present invention include a method of applying the curable resin composition onto a support film and then drying it to form a resin composition layer on the support film. When the curable resin composition of the present invention is used for the build-up film, it is important that the film is softened under a temperature condition of lamination in vacuum lamination (usually 70 to 140° C.) and to exhibit flowability (resin flow) enabling resin filling in via holes or through holes present in the circuit board at the same time as the lamination of the circuit board, and it is preferable to blend the above components so as to exhibit such characteristics.

Here, the diameter and the depth of the through holes in the circuit board are usually 0.1 to 0.5 mm and 0.1 to 1.2 mm, respectively, and it is usually preferable to enable resin filling within these ranges. When laminating both sides of the circuit board, it is desirable to fill about ½ of the through holes.

Specific examples of the method for manufacturing the build-up film described above include a method of preparing a resin composition varnished by blending an organic solvent, then applying the varnished resin composition to the surface of a support film (Y), and drying the organic solvent by heating, hot air blowing, or the like to form a resin composition layer (X).

Preferred examples of the organic solvent used here include ketones such as acetone, methyl ethyl ketone, and cyclohexanone, acetates such as ethyl acetate, butyl acetate, cellosolve acetate, propylene glycol monomethyl ether acetate, and carbitol acetate, cellosolve, carbitols such as butyl carbitol, aromatic hydrocarbons such as toluene and xylene, dimethylformamide, dimethylacetamide, and N-methylpyrrolidone, which are preferably used at a ratio of a non-volatile content of 30 to 60% by mass.

The thickness of the resin composition layer (X) to be formed is usually required to be the thickness of the conductor layer or more. The thickness of the conductor layer that the circuit board has is usually in a range of 5 to 70 μm, and thus the thickness of the resin composition layer (X) preferably has a thickness of 10 to 100 μm. The resin composition layer (X) in the present invention may be protected by a protective film, which is described below. Protection by the protective film can prevent dust and the like from adhering to the surface of the resin composition layer or scratches thereon.

Examples of the support film and the protective film include polyolefins such as polyethylene, polypropylene, and polyvinyl chloride, polyesters such as polyethylene terephthalate (PET) and polyethylene naphthalate, polycarbonates, polyimides, and even mold release paper and metal foil such as copper foil and aluminum foil. The support film and the protective film may be treated with mold release treatment in addition to mad treatment and corona treatment. The thickness of the support film, which is not limited to a particular thickness, is usually 10 to 150 μm and is preferably used in a range of 25 to 50 μm. The thickness of the protective film is preferably 1 to 40 μm.

The support film (Y) is peeled off after being laminated onto the circuit board or after forming an insulating layer by heat curing. If the support film (Y) is peeled off after the resin composition layer forming the build-up film is heat cured, adhesion of dust and the like during the curing step can be prevented. When being peeled off after curing, the support film is usually treated with mold release treatment in advance.

A multilayer printed circuit board can be manufactured from the build-up film obtained as described above. When the resin composition layer (X) is protected by the protective films, for example, these are peeled off, and then the resin composition layer (X) is laminated to one or both sides of the circuit board so as to be in direct contact with the circuit board by vacuum lamination, for example. The method of lamination may be a batch type or a continuous type with rolls. If necessary, the build-up film and the circuit board may be heated (preheated) as required before performing lamination. As the conditions for lamination, the compression bonding temperature (lamination temperature) is preferably 70 to 140° C., the compression bonding pressure is preferably 1 to 11 kgf/cm² (9.8×104 to 107.9×104 N/m²), and lamination is preferably performed with air pressure reduced to 20 mmHg (26.7 hPa) or less.

### <Conductive Paste>

Examples of the method for obtaining a conductive paste from the curable resin composition of the present invention include a method of dispersing conductive particles in the composition. The conductive paste can be a paste resin composition for circuit connection or an anisotropic conductive adhesive, depending on the type of the used conductive particles.

The following describes the present invention specifically by means of examples and comparative examples, in which “part(s)” and “%” are on a mass basis unless otherwise specified. Curable resins or curable compounds and curable resin films obtained using the curable resins or curable compounds were produced under the following conditions, and furthermore, the obtained curable resin films were measured or calculated and evaluated under the following conditions.

### <GPC Measurement (Evaluation of Weight Average Molecular Weight (Mw) of Curable Resin)>

Measurement was conducted using the following measurement apparatus and measurement conditions to obtain GPC charts of the curable resins obtained by the method of production indicated below. The weight average molecular weights (Mw) of the curable resins were calculated from the results of the GPC charts (the GPC charts are not illustrated).
Measurement apparatus: “HLC-8320 GPC” manufactured by Tosoh Corporation
Column: Guard column “HXL-L” manufactured by Tosoh Corporation+“TSK-GEL G2000HXL” manufactured by Tosoh Corporation+“TSK-GEL G2000HXL” manufactured by Tosoh Corporation+“TSK-GEL G3000HXL” manufactured by Tosoh Corporation+“TSK-GEL G4000HXL” manufactured by Tosoh Corporation
Detector: RI (differential refractometer)
Data processing: “GPC Workstation EcoSEC-WorkStation” manufactured by Tosoh Corporation
Measurement conditions: Column temperature 40° C.
   Developing solvent tetrahydrofuran
   Flow rate 1.0 ml/minute
Standard: The following monodispersed polystyrenes of known molecular weights were used in conformity with the measurement manual of the “GPC Workstation EcoSEC-WorkStation.”

### (Polystyrenes Used)

“A-500” manufactured by Tosoh Corporation
“A-1000” manufactured by Tosoh Corporation
“A-2500” manufactured by Tosoh Corporation
“A-5000” manufactured by Tosoh Corporation
“F-1” manufactured by Tosoh Corporation
“F-2” manufactured by Tosoh Corporation
“F-4” manufactured by Tosoh Corporation
“F-10” manufactured by Tosoh Corporation
“F-20” manufactured by Tosoh Corporation
“F-40” manufactured by Tosoh Corporation
“F-80” manufactured by Tosoh Corporation
“F-122” manufactured by Tosoh Corporation

Sample: A microfiltered tetrahydrofuran solution (50 μl) of 1.0% by mass in terms of solid content of the curable resin obtained in production examples.

### (Production Example 1) Preparation of Curable Resin (A-1)

Into a 200 ml three-necked flask equipped with a cooling tube, 67.2 g (0.55 mol) of 2,6-xylenol and 53.7 g of 96% sulfuric acid were charged and dissolved in 30 ml of methanol with nitrogen flow. The temperature was raised to 70° C. in an oil bath, and 25 g (0.125 mol) of a 50% aqueous glutaraldehyde solution was added thereto over 6 hours with stirring and reacted for 12 hours with stirring. After the end of the reaction, the obtained reaction mixture (reaction solution) was cooled to room temperature (25° C.), 200 ml of toluene was added to this reaction solution, which was then washed using 200 ml of water. Subsequently, the obtained organic phase was poured into 500 mL of hexane, and the solid precipitated thereby was filtered off and vacuum dried to obtain 22 g (0.039 mol) of an intermediate phenolic compound.

In a 200 mL flask equipped with a thermometer, a cooling tube, and a stirrer, 20 g of toluene and 22 g (0.039 mol) of the intermediate phenolic compound were mixed together and heated to about 85° C. Dimethylaminopyridine in an amount of 0.19 g (0.0016 mol) was added thereto. After all the solids were dissolved, 38.5 g (0.25 mol) of methacrylic anhydride was gradually added thereto. The obtained solution was maintained at a state of 85° C. for 3 hours with mixing.

Next, the obtained solution was cooled to room temperature (25° C.) and added dropwise into 360 g of hexane, which was vigorously stirred with a magnetic stirrer in a 1 L beaker, over 30 minutes. The obtained precipitate was filtered out under reduced pressure and dried to obtain 38 g of a curable resin (A-1) with the following structural formula.

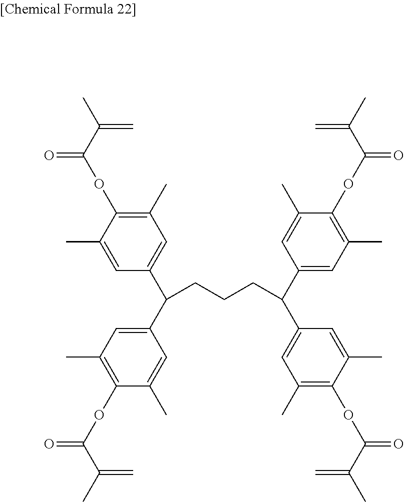 [SMILES: C=C(C)C(=O)Oc1c(C)cc(C(CCCC(c2cc(C)c(OC(=O)C(=C)C)c(C)c2)c2cc(C)c(OC(=O)C(=C)C)c(C)c2)c2cc(C)c(OC(=O)C(=C)C)c(C)c2)cc1C]

### (Production Example 2) Preparation of Curable Resin (A-2)

Into a 200 ml three-necked flask equipped with a cooling tube, 104.7 g (0.55 mol) of 2-cyclohexyl-5-methylphenol and 53.7 g of 96% sulfuric acid were charged and dissolved in 30 ml of methanol with nitrogen flow. The temperature was raised to 70° C. in an oil bath, and 25 g (0.125 mol) of a 50% aqueous glutaraldehyde solution was added thereto over 6 hours with stirring and reacted for 12 hours with stirring. After the end of the reaction, the obtained reaction mixture (reaction solution) was cooled to room temperature (25° C.), 200 ml of toluene was added to this reaction solution, which was then washed using 200 ml of water. Subsequently, the obtained organic phase was poured into 500 mL of hexane, and the solid precipitated thereby was filtered off and vacuum dried to obtain 32.2 g (0.039 mol) of an intermediate phenolic compound.

In a 200 mL flask equipped with a thermometer, a cooling tube, and a stirrer, 20 g of toluene and 32.2 g (0.039 mol) of the intermediate phenolic compound were mixed together and heated to about 85° C. Dimethylaminopyridine in an amount of 0.19 g (0.0016 mol) was added thereto. After all the solids were dissolved, 38.5 g (0.25 mol) of methacrylic anhydride was gradually added thereto. The obtained solution was maintained at a state of 85° C. for 3 hours with mixing.

Next, the obtained solution was cooled to room temperature (25° C.) and added dropwise into 360 g of hexane, which was vigorously stirred with a magnetic stirrer in a 1 L beaker, over 30 minutes. The obtained precipitate was filtered out under reduced pressure and dried to obtain 40 g of a curable resin (A-2) with the following structural formula.

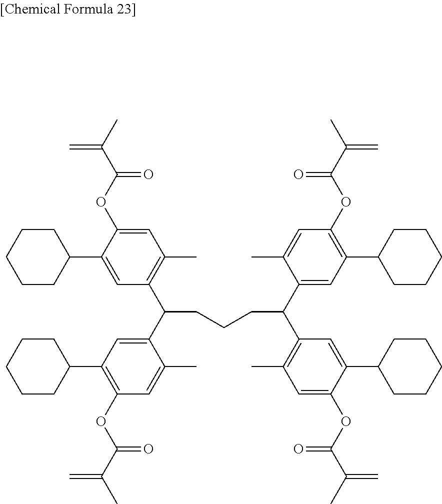 [SMILES: C=C(C)C(=O)Oc1cc(C)c(C(CCCC(c2cc(C3CCCCC3)c(OC(=O)C(=C)C)cc2C)c2cc(C3CCCCC3)c(OC(=O)C(=C)C)cc2C)c2cc(C3CCCCC3)c(OC(=O)C(=C)C)cc2C)cc1C1CCCCC1]

### (Production Example 3) Preparation of Curable Resin (A-3)

Into a reaction vessel equipped with a stirrer, 113.8 parts by mass of 2,2-bis(4-hydroxy-3,5-dimethylphenyl)propane, 64.0 parts by mass of sodium hydroxide, 0.25 part by mass of tri-n-butylbenzylammonium chloride, and 2,000 parts by mass of pure water were charged for dissolution to prepare an aqueous phase. In 1,500 parts by mass of methylene chloride, 30.5 parts by mass of terephthaloyl dichloride, 30.5 parts by mass of isophthaloyl dichloride, and 20.9 parts by mass of methacryloyl chloride were dissolved to prepare an organic phase.

With the aqueous phase stirred in advance, the organic phase was added to the aqueous phase under strong stirring and reacted at 20° C. for 5 hours. Subsequently, the stirring was stopped, the aqueous phase and the organic phase were separated from each other, and the organic phase was washed 10 times with pure water. Subsequently, methylene chloride was distilled under reduced pressure from the organic phase using an evaporator, and the polymer was dried and solidified. The obtained polymer was dried under reduced pressure to obtain a curable resin (A-3) with a weight average molecular weight of 3,100 having the following repeating unit and having a methacryloyloxy group at the end:

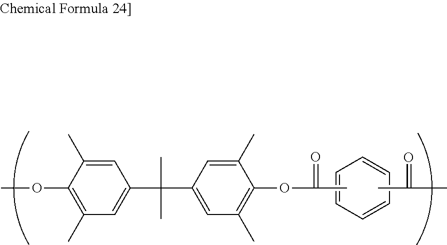

### (Production Example 4) Preparation of Curable Resin (A-4)

Synthesis was carried out in the same manner as in Production Example 3 above except that 2,2-bis(4-hydroxy-3,5-dimethylphenyl)propane in Production Example 3 above was changed to 102.5 parts by mass of bis(4-hydroxy-3,5-dimethylphenyl)methane to obtain a curable resin (A-4) with a weight average molecular weight of 2,900 having the following repeating unit and having a methacryloyloxy group at the end:

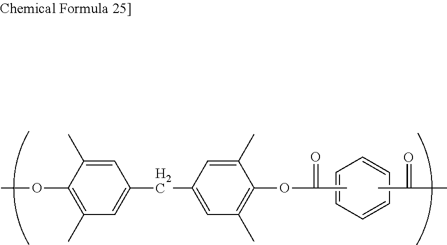

### (Production Example 5) Preparation of Curable Resin (A-5)

Into a 1 L flask equipped with a thermometer, a cooling tube, a Dean Stark trap, and a stirrer, 48.9 g (0.4 mol) of 2,6-dimethylphenol, 272.0 g (1.4 mol) of α,α′-dihydroxy-1,3-diisopropylbenzene, 220 g of xylene, and 70 g of activated white clay were charged, and heated to 120° C. with stirring. The temperature was raised to 210° C. while the distillate water is removed by a Dean stark tube, and reaction was conducted for 3 hours. The temperature was then cooled to 140° C., 146.6 g (1.2 mol) of 2,6-dimethylphenol was charged thereinto, the temperature was then raised up to 220° C., and reaction was conducted for 3 hours. After the reaction, the resultant product was air cooled to 100° C., diluted with 300 g toluene, filtered to remove the activated white clay, and the solvent and low-molecular weight substances such as an unreacted substance were distilled off under reduced pressure to obtain 365.3 g of an intermediate phenolic compound. The hydroxy group equivalent (phenol equivalent) of the obtained intermediate phenolic compound was 299.

Into a 2 L flask equipped with a thermometer, a cooling tube, and a stirrer, 365.3 g of the obtained intermediate phenolic compound and 700 g of toluene were charged and stirred at about 85° C. Next, dimethylaminopyridine in an amount of 29.9 g (0.24 mol) was charged thereinto. When all the solids appeared to be dissolved, 277.5 g (1.8 mol) of methacrylic anhydride was added dropwise thereto over 1 hour. After the end of dropwise addition, reaction was conducted at 85° C. for further 3 hours. The reaction solution was added dropwise into 4,000 g of methanol, which was vigorously stirred with a magnetic stirrer in a 5 L beaker, over 1 hour. The obtained precipitate was filtered out under reduced pressure through a membrane filter and dried to obtain a curable resin (A-5) with a weight average molecular weight of 1,500 having an indane skeleton of the following structural formula.

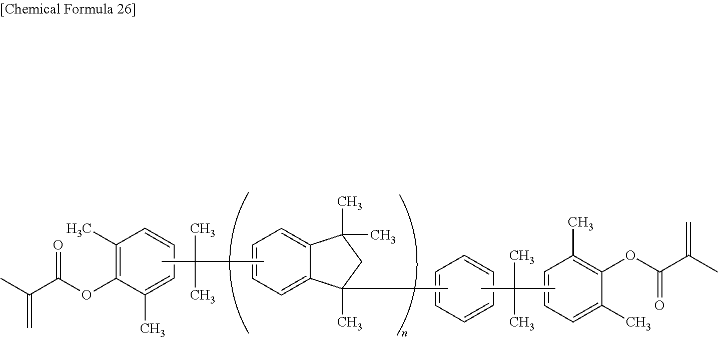

### (Production Example 6) Preparation of Curable Resin (A-6)

Synthesis was carried out in the same manner as in Production Example 5 above except that 2,6-dimethylphenol in Production Example 5 above was changed to 224.76 g (1.8 mol) of 2-methyl-1-naphthol to obtain a curable resin (A-6) with a weight average molecular weight of 1,500 having an indane skeleton of the following structural formula.

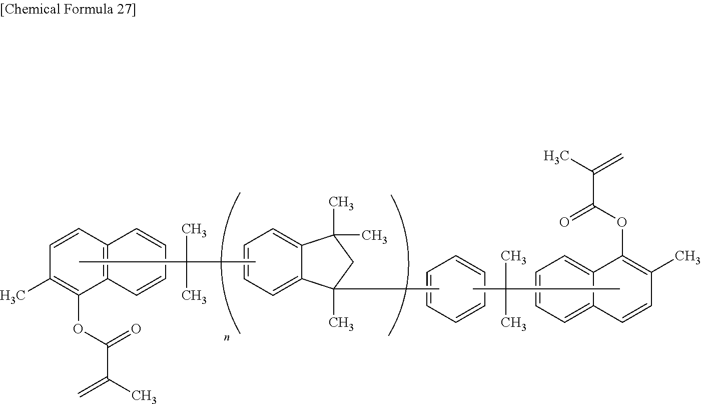

### (Production Example 7) Preparation of Curable Compound (B-1)

As a curable resin, commercially available 4-tert-butylstyrene (manufactured by Sigma-Aldrich) was used as a curable compound (B-1).

### (Production Example 8) Preparation of Curable Compound (B-2)

As a curable resin, commercially available divinylbenzene (manufactured by Sigma-Aldrich) was used as a curable compound (B-2).

### (Production Example 9) Preparation of Curable Compound (B-3)

As a curable resin, commercially available 2-vinylnaphthalene (manufactured by Sigma-Aldrich) was used as a curable compound (B-3).

### (Production Example 10) Preparation of Curable Resin (B-4)

Into a reaction vessel equipped with a stirrer, 3.0 mol (390.6 g) of divinylbenzene, 1.8 mol (229.4 g) of ethylvinylbenzene, 10.2 mol (1,066.3 g) of styrene, and 15.0 mol (1,532.0 g) of n-propyl acetate were charged, and 600 mmol of a boron trifluoride diethyl ether complex was added thereto at 70° C. and reacted for 4 hours. After the polymerization solution was stopped with an aqueous sodium bicarbonate solution, the oil layer was washed with pure water three times and devolatilized under reduced pressure at 60° C. to collect a copolymer. A curable resin (B-4) with a weight average molecular weight of 40,000 containing a vinylbenzyl group was obtained.

### (Production Example 11) Preparation of Curable Resin (A-7)

As a curable resin, commercially available 4,4′-isopropylidene diphenol dimethacrylate (manufactured by Sigma-Aldrich) was used as a curable resin (A-7).

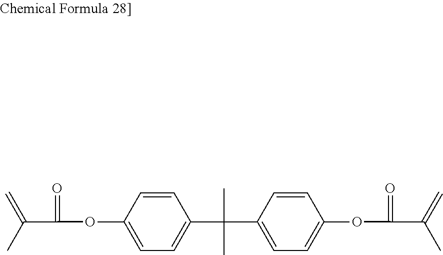 [SMILES: C=C(C)C(=O)Oc1ccc(C(C)(C)c2ccc(OC(=O)C(=C)C)cc2)cc1]

### <Preparation of Curable Resin Composition>

Using the curable resins or the curable compounds obtained in the production examples, based on the curable resin compositions with the blending details (raw materials and blending amounts) listed in Table 1 or Table 2 below and the conditions described below (temperature, time, and the like), samples for evaluation (resin films (cured products)) were prepared, and were evaluated as examples and comparative examples.

### <Production of Resin Film (Cured Product)>

Each of the curable resin compositions was put into a 5 cm-square mold frame, was held between stainless plates, and was set in a vacuum press. It was pressurized up to 1.5 MPa under normal pressure and temperature. Next, the pressure was reduced to 10 torr and was then heated to a temperature 50° C. above a thermal curing temperature over 30 minutes. After being left at rest for 2 hours, it was gradually cooled to room temperature to obtain a uniform resin film (cured product) with an average thickness of 100 μm.

### <Evaluation of Dielectric Properties>

As to the dielectric properties of the obtained resin film (cured product) in the in-plane direction, a dielectric constant and a dielectric loss tangent were measured at a frequency of 10 GHz by the split-post dielectric resonator method using a network analyzer N5247A of Keysight Technologies.

As to the dielectric loss tangent, if it is 10.0×10⁻³ or less, there is no problem in practical use, and it is preferably 3.0×10⁻³ or less and more preferably 2.5×10⁻³ or less. The dielectric loss tangent is particularly preferably 2.0×10⁻³ or less. As to the dielectric constant, if it is 3 or less, there is no problem in practical use, and it is preferably 2.7 or less and more preferably 2.5 or less.

### <Evaluation of Heat Resistance (Glass Transition Temperature)>

For the obtained resin film (cured product), using a DSC apparatus (Pyris Diamond) manufactured by Perkin Elmer, a peak exothermic temperature (a thermal curing temperature) observed when measured at a temperature increase condition of 20° C./minute from 30° C. was observed, and then it was held at a temperature 50° C. above it for 30 minutes. Next, the sample was cooled to 30° C. at a temperature decrease condition of 20° C./minute, and furthermore, the temperature was again increased at a temperature increase condition of 20° C./minute to measure the glass transition temperature (Tg) (° C.) of the resin film (the cured product).

As to the glass transition temperature (Tg), if it is 100° C. or higher, there is no problem in practical use, and it is preferably 150° C. or higher and more preferably 200° C. or higher.

### <Evaluation of Heat Resistance>

The obtained resin film (cured product) was measured using a TG-DTA apparatus (TG-8120) manufactured by Rigaku Corporation at a temperature increase rate of 20° C./minute under a nitrogen flow of 20 mL/minute to measure a 5% weight loss temperature (Td5).

TABLE 1

| | Comparative | Comparative | Comparative | Example | Example | Example | Example | Example | Example | Example |
|---|---|---|---|---|---|---|---|---|---|---|
| | Example 1 | Example 2 | Example 3 | 1 | 2 | 3 | 4 | 5 | 6 | 7 |
| A-1 | | | | 70 | 70 | 70 | 70 | | | |
| A-2 | | | | | | | | 70 | | |
| A-3 | | | | | | | | | 70 | |
| A-4 | | | | | | | | | | 70 |
| A-5 | | | | | | | | | | |
| A-6 | | | | | | | | | | |
| A-7 | 100 | 70 | | | | | | | | |
| B-1 | | 30 | 100 | 30 | | | | 30 | 30 | 30 |
| B-2 | | | | | 30 | | | | | |
| B-3 | | | | | | 30 | | | | |
| B-4 | | | | | | | 30 | | | |
| Dielectric | 17 | 12 | 1.9 | 1.8 | 1.8 | 1.9 | 1.9 | 2.2 | 2.0 | 1.8 |
| loss tangent | | | | | | | | | | |
| (×10⁻³) | | | | | | | | | | |
| Dielectric | 2.7 | 2.6 | 2.4 | 2.3 | 2.3 | 2.3 | 2.3 | 2.5 | 2.4 | 2.3 |
| constant | | | | | | | | | | |
| Tg (° C.) | 89 | 94 | 132 | 200 | 210 | 220 | 240 | 208 | 210 | 220 |

TABLE 2

| | Example | Example | Example | Example | Example | Example | Example | Example | Example |
|---|---|---|---|---|---|---|---|---|---|
| | 8 | 9 | 10 | 11 | 12 | 13 | 14 | 15 | 16 |
| A-1 | | | 99.5 | 99 | 95 | 50 | 10 | 5 | 50 |
| A-2 | | | | | | | | | |
| A-3 | | | | | | | | | |
| A-4 | | | | | | | | | 20 |
| A-5 | 70 | | | | | | | | |
| A-6 | | 70 | | | | | | | |
| A-7 | | | | | | | | | |
| B-1 | 30 | 30 | 0.5 | 1 | 5 | 50 | 90 | 95 | 30 |
| B-2 | | | | | | | | | |
| B-3 | | | | | | | | | |
| B-4 | | | | | | | | | |
| Dielectric | 1.8 | 2.3 | 2.0 | 1.9 | 1.8 | 1.8 | 1.8 | 1.8 | 1.8 |
| loss tangent | | | | | | | | | |
| (×10⁻³) | | | | | | | | | |
| Dielectric | 2.3 | 2.6 | 2.3 | 2.3 | 2.3 | 2.3 | 2.3 | 2.4 | 2.3 |
| constant | | | | | | | | | |
| Tg (° C.) | 202 | 210 | 195 | 200 | 200 | 205 | 200 | 180 | 230 |

From the evaluation results in Table 1 and Table 2 above, it was confirmed that in all the examples the cured products obtained by using the desired curable resin compositions were able to achieve both heat resistance and low dielectric properties, which were on a level with no practical problem. On the other hand, in Comparative Examples 1 and 2, it was confirmed that the dielectric loss tangent was high because they do not have any substituent inhibiting the molecular mobility of the methacryloyloxy group in the compound. In Comparative Examples 1 to 3, it was confirmed that the heat resistance of the cured product reduced because only either the methacryloyloxy group-containing compound or the aromatic vinyl group-containing compound was contained.

1. A curable resin composition comprising a curable resin (A) having a structure represented by General Formula (1) below and a curable resin (B1) having a structure represented by General Formula (2-1) below and/or a curable compound (B2) represented by General Formula (2-2) below: 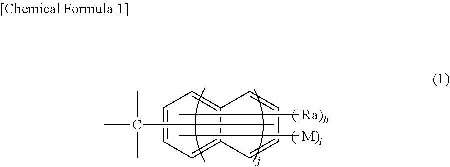
in General Formula (1) above, Ras are each independently an alkyl group, an aryl group, an aralkyl group, or a cycloalkyl group with a carbon number of 1 to 12; M is a methacryloyloxy group; h and i each independently indicate an integer of 1 to 4; and j indicates an integer of 0 to 2: 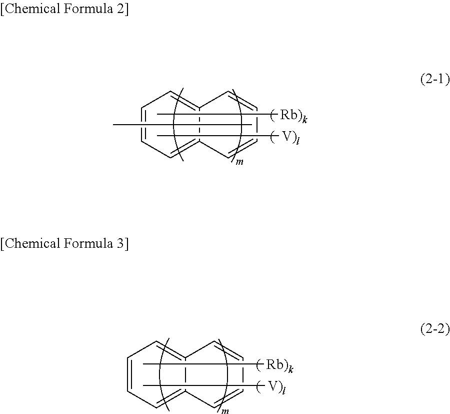
in General Formulae (2-1) and (2-2) above, Rbs are each independently an alkyl group, an aryl group, an aralkyl group, or a cycloalkyl group with a carbon number of 1 to 12; V is a vinyl group; k indicates an integer of 0 to 4; 1 indicates an integer of 1 to 4; and m indicates an integer of 0 to 2.

2. The curable resin composition according to claim 1, wherein a mass of the curable resin (A) and a total mass of the curable resin (B1) and the curable compound (B2) are 99:1 to 10:90 in terms of mass ratio.

3. The curable resin composition according to claim 1, wherein in General Formula (1) above, at least one substituent Ra is positioned at an ortho position of the substituent M.

4. The curable resin composition according to claim 3, wherein General Formula (1) above is represented by General Formula (1-1) below: 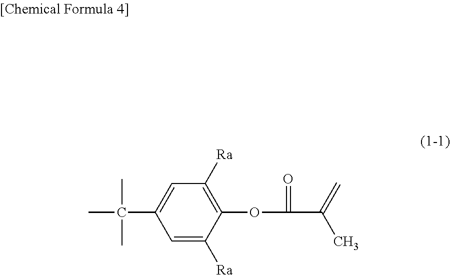
in General Formula (1-1) above, Ras are each independently an alkyl group, an aryl group, an aralkyl group, or a cycloalkyl group with a carbon number of 1 to 12.

5. The curable resin composition according to claim 1, wherein the curable resin (A) is one or more selected from the group consisting of:
a curable resin (A1) represented by General Formula (A1) below;
a curable resin (A2) having a repeating structure represented by General Formula (A2a) below and a terminal structure represented by General Formula (A2b) below; and
a curable resin (A3) having a repeating structure represented by General Formula (A3a) below and a terminal structure represented by General Formula (A3b) below: 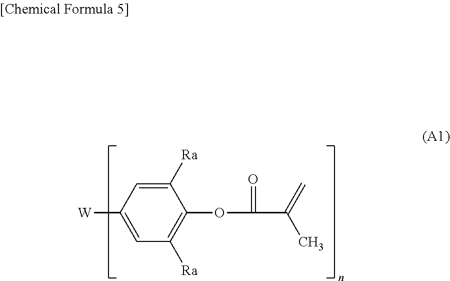
in General Formula (A1) above, Ras are each independently an alkyl group, an aryl group, an aralkyl group, or a cycloalkyl group with a carbon number of 1 to 12; W is a hydrocarbon with a carbon number of 2 to 15; and n is an integer of 3 to 5: 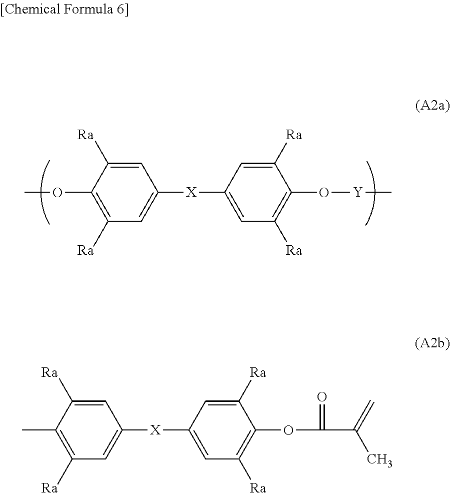
in General Formula (A2a) or General Formula (A2b) above, Ras are each independently an alkyl group, an aryl group, an aralkyl group, or a cycloalkyl group with a carbon number of 1 to 12; X represents a hydrocarbon group; and Y is represented by any of General Formulae (Y1) to (Y3) below: 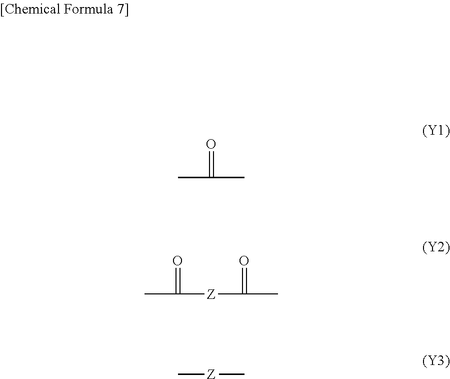
in General Formulae (Y1) to (Y3) above, Z represents an alicyclic group, an aromatic group, or a heterocyclic group: 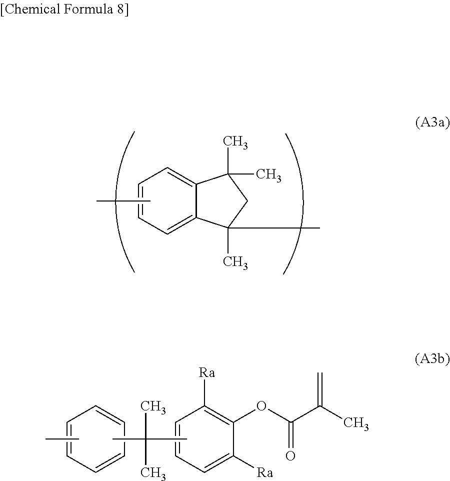
in General Formula (A3b) above, Ras are each independently an alkyl group, an aryl group, an aralkyl group, or a cycloalkyl group with a carbon number of 1 to 12.

6. The curable resin composition according to claim 1, wherein General Formula (2-1) above is represented by General Formula (2-1-1) below: 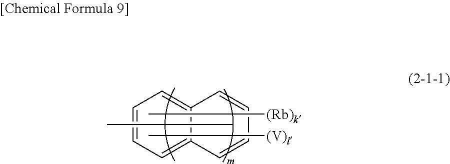
in General Formula (2-1-1) above, Rbs are each independently an alkyl group, an aryl group, or an aralkyl group with a carbon number of 1 to 12; V is a vinyl group, k′ indicates an integer of 0 to 2; P indicates an integer of 1 or 2; and m indicates an integer of 0 to 2.

7. The curable resin composition according to claim 1, wherein General Formula (2-2) above is represented by General Formula (2-2-1) below: 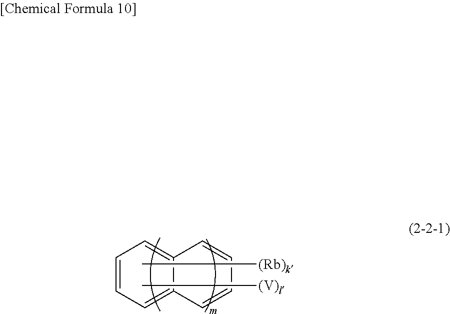
in General Formula (2-2-1) above, Rbs are each independently an alkyl group, an aryl group, or an aralkyl group with a carbon number of 1 to 12; V is a vinyl group, k′ indicates an integer of 0 to 2; P indicates an integer of 1 or 2; and m indicates an integer of 0 to 2.

8. A cured product obtained by subjecting the curable resin composition according to claim 1 to a curing reaction.

9. A varnish obtained by diluting the curable resin composition according to claim 1 with an organic solvent.

10. A prepreg comprising:
a reinforcing base material; and
a semi-cured product of the varnish according to claim 9 impregnated into the reinforcing base material.

11. A circuit board obtained by laminating and thermocompression molding the prepreg according to claim 10 and copper foil to each other.

12. The curable resin composition according to claim 2, wherein in General Formula (1) above, at least one substituent Ra is positioned at an ortho position of the substituent M.

13. The curable resin composition according to claim 2, wherein the curable resin (A) is one or more selected from the group consisting of:
a curable resin (A1) represented by General Formula (A1) below;
a curable resin (A2) having a repeating structure represented by General Formula (A2a) below and a terminal structure represented by General Formula (A2b) below; and
a curable resin (A3) having a repeating structure represented by General Formula (A3a) below and a terminal structure represented by General Formula (A3b) below: 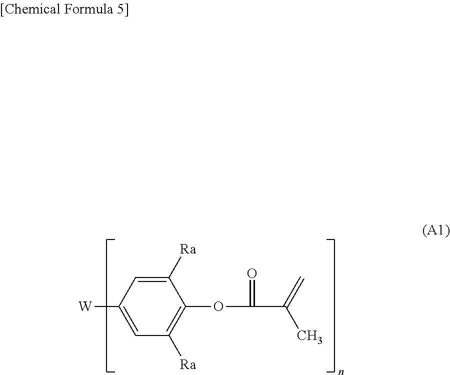
in General Formula (A1) above, Ras are each independently an alkyl group, an aryl group, an aralkyl group, or a cycloalkyl group with a carbon number of 1 to 12; W is a hydrocarbon with a carbon number of 2 to 15; and n is an integer of 3 to 5: 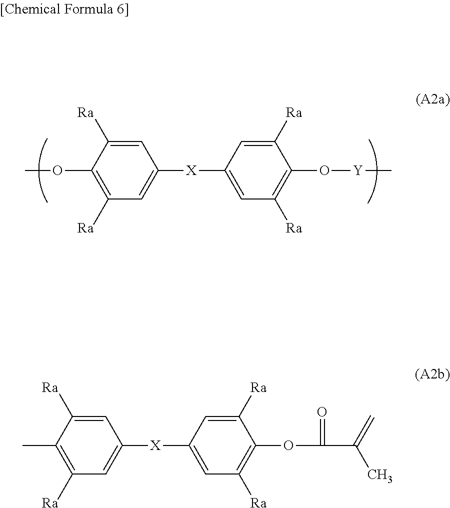
in General Formula (A2a) or General Formula (A2b) above, Ras are each independently an alkyl group, an aryl group, an aralkyl group, or a cycloalkyl group with a carbon number of 1 to 12; X represents a hydrocarbon group; and Y is represented by any of General Formulae (Y1) to (Y3) below: 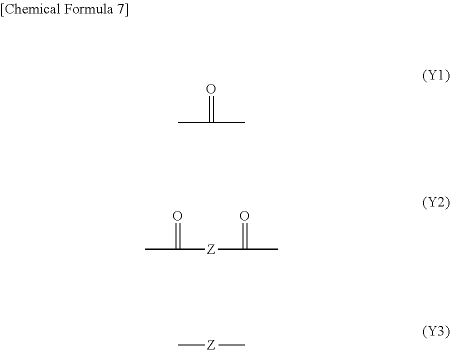
in General Formulae (Y1) to (Y3) above, Z represents an alicyclic group, an aromatic group, or a heterocyclic group: 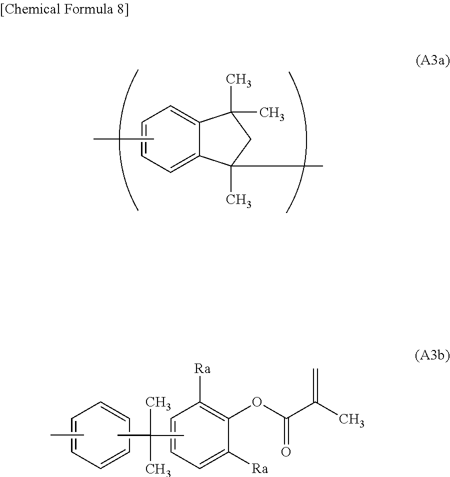
in General Formula (A3b) above, Ras are each independently an alkyl group, an aryl group, an aralkyl group, or a cycloalkyl group with a carbon number of 1 to 12.

14. The curable resin composition according to claim 3, wherein the curable resin (A) is one or more selected from the group consisting of:
a curable resin (A1) represented by General Formula (A1) below;
a curable resin (A2) having a repeating structure represented by General Formula (A2a) below and a terminal structure represented by General Formula (A2b) below; and
a curable resin (A3) having a repeating structure represented by General Formula (A3a) below and a terminal structure represented by General Formula (A3b) below: 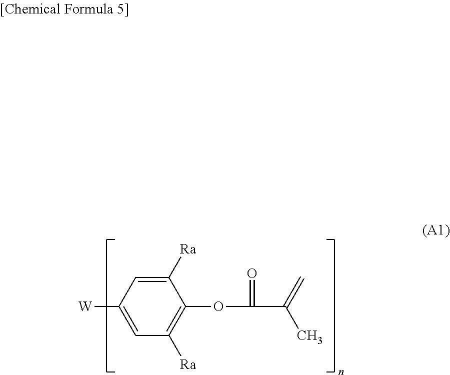
in General Formula (A1) above, Ras are each independently an alkyl group, an aryl group, an aralkyl group, or a cycloalkyl group with a carbon number of 1 to 12; W is a hydrocarbon with a carbon number of 2 to 15; and n is an integer of 3 to 5: 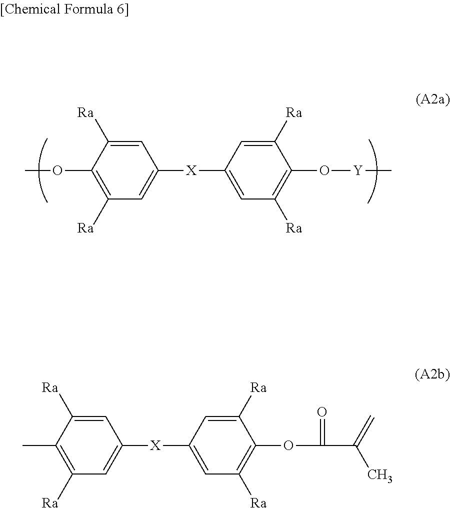
in General Formula (A2a) or General Formula (A2b) above, Ras are each independently an alkyl group, an aryl group, an aralkyl group, or a cycloalkyl group with a carbon number of 1 to 12; X represents a hydrocarbon group; and Y is represented by any of General Formulae (Y1) to (Y3) below: 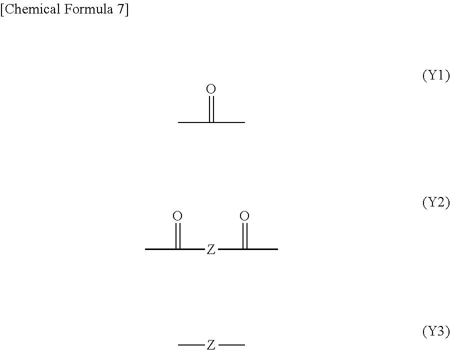
in General Formulae (Y1) to (Y3) above, Z represents an alicyclic group, an aromatic group, or a heterocyclic group: 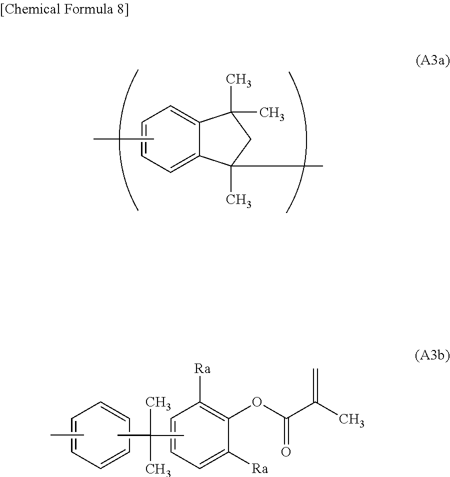
in General Formula (A3b) above, Ras are each independently an alkyl group, an aryl group, an aralkyl group, or a cycloalkyl group with a carbon number of 1 to 12.

15. The curable resin composition according to claim 4, wherein the curable resin (A) is one or more selected from the group consisting of:
a curable resin (A1) represented by General Formula (A1) below;
a curable resin (A2) having a repeating structure represented by General Formula (A2a) below and a terminal structure represented by General Formula (A2b) below; and
a curable resin (A3) having a repeating structure represented by General Formula (A3a) below and a terminal structure represented by General Formula (A3b) below: 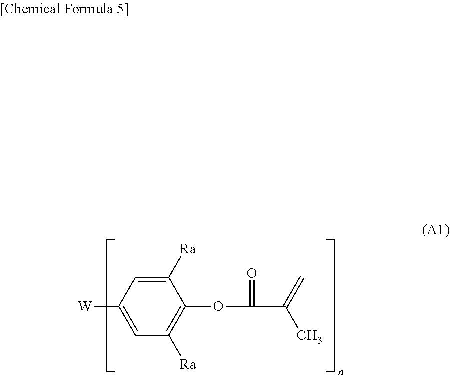
in General Formula (A1) above, Ras are each independently an alkyl group, an aryl group, an aralkyl group, or a cycloalkyl group with a carbon number of 1 to 12; W is a hydrocarbon with a carbon number of 2 to 15; and n is an integer of 3 to 5: 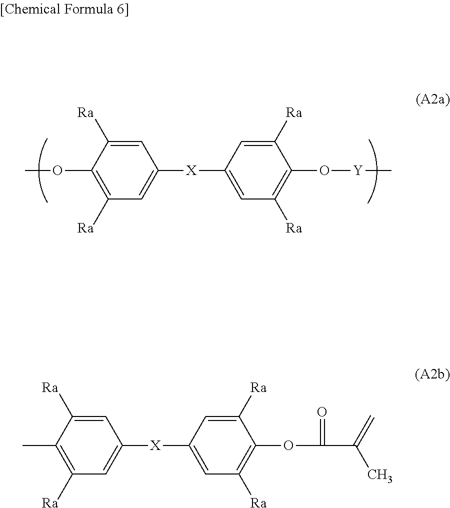
in General Formula (A2a) or General Formula (A2b) above, Ras are each independently an alkyl group, an aryl group, an aralkyl group, or a cycloalkyl group with a carbon number of 1 to 12; X represents a hydrocarbon group; and Y is represented by any of General Formulae (Y1) to (Y3) below: 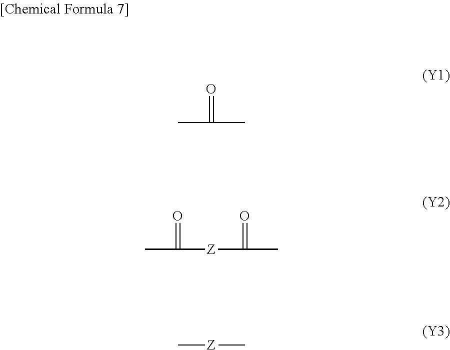
in General Formulae (Y1) to (Y3) above, Z represents an alicyclic group, an aromatic group, or a heterocyclic group: 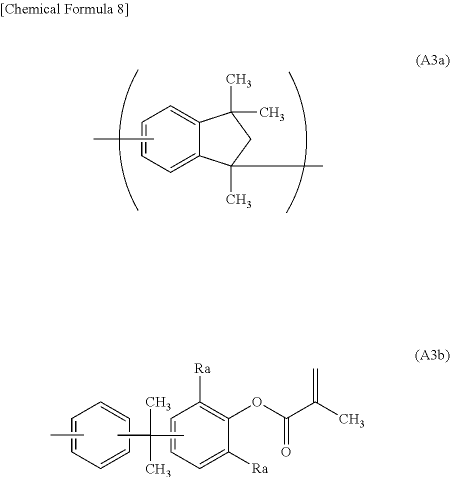
in General Formula (A3b) above, Ras are each independently an alkyl group, an aryl group, an aralkyl group, or a cycloalkyl group with a carbon number of 1 to 12.

16. The curable resin composition according to claim 2, wherein General Formula (2-1) above is represented by General Formula (2-1-1) below: 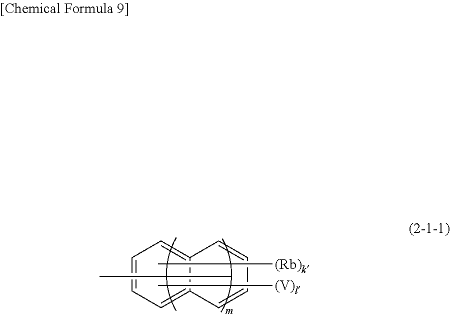
in General Formula (2-1-1) above, Rbs are each independently an alkyl group, an aryl group, or an aralkyl group with a carbon number of 1 to 12; V is a vinyl group, k′ indicates an integer of 0 to 2; P indicates an integer of 1 or 2; and m indicates an integer of 0 to 2.

17. The curable resin composition according to claim 2, wherein General Formula (2-2) above is represented by General Formula (2-2-1) below: 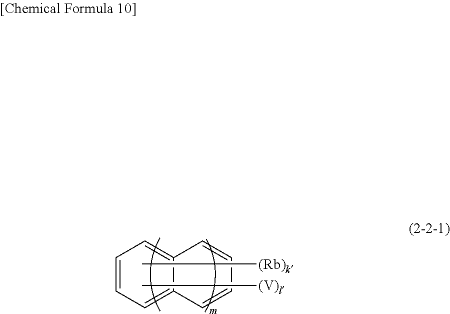
in General Formula (2-2-1) above, Rbs are each independently an alkyl group, an aryl group, or an aralkyl group with a carbon number of 1 to 12; V is a vinyl group, k′ indicates an integer of 0 to 2; P indicates an integer of 1 or 2; and m indicates an integer of 0 to 2.

18. A cured product obtained by subjecting the curable resin composition according to claim 2 to a curing reaction.

19. A cured product obtained by subjecting the curable resin composition according to claim 3 to a curing reaction.

20. A varnish obtained by diluting the curable resin composition according to claim 2 with an organic solvent.
